(19) United States
(12) Patent Application Publication
(10) Pub. No.: US 2011/0192857 A1
(43) Pub. Date: Aug. 11, 2011

(54) Magnetically Attached Accessories (For A Case) for a Portable Electronics Device

(76) Inventors: Wayne Philip Rothbaum, New York, NY (US); Robert B. Curtis, New York, NY (US)

(21) Appl. No.: 13/006,374

(22) Filed: Jan. 13, 2011

Related U.S. Application Data
(63) Continuation-in-part of application No. 12/338,680, filed on Dec. 18, 2008.
Application No. 12/338,680 is a continuation-in-part of application No. 12/908,216, filed on Oct. 20, 2010.

(51) Int. Cl. B65D 25/20; H01F 7/02; A44B 18/00; F16B 47/00; A44B 11/00; A44B 17/00; A44B 1/00; A47F 7/00; H05K 7/00; F16M 13/02; F16B 2/20; B25F 1/00; B60R 11/02; G08B 1/08; H02J 7/00

(52) U.S. Cl. 220/694; 24/303; 24/442; 24/304; 24/163 R; 24/591.1; 24/90.1; 211/70.6; 248/206.5; 248/220.21; 248/231.81; 7/169; 224/400; 340/539.11; 320/107

(57) ABSTRACT

A mobile electronic device accessory system is provided. The accessory system comprises a mobile electronic device case with a surface and a first attachment mechanism. An accessory is also provided, where the accessory comprises a second attachment mechanism, and is removably attached to the surface of the mobile electronic device case. In some embodiments, the case comprises a back with a recessed portion configured to receive an accessory therein, and an attachment mechanism for removably attaching the accessory to the case. Methods of using the accessory system are also provided.

### RELATED APPLICATIONS

This application is a continuation in part of U.S. patent application Ser. No. 12/338,680 (File No. 066501-5001-US), filed on Dec. 18, 2008, entitled “Magnetic Cord Management System,” and of U.S. patent application Ser. No. 12/908,216 (File No. 066501-5005-US), filed on Oct. 20, 2010, entitled “Cord Management System,” the disclosures of which are all incorporated herein by reference in their entirety.

This application is related to PCT Patent Application No. PCT/US2010/053244, filed on Oct. 19, 2010, entitled “Cord Management System,” which is a continuation in part of PCT Patent Application No. PCT/US2010/031087, filed on Apr. 14, 2010, entitled “Cord Management System.” This application is also related to U.S. patent application Ser. No. 12/908,256 (File No. 066501-5005-US01), filed on Oct. 20, 2010, entitled “Cord Management System.” This application is also related to U.S. Design patent application Ser. No. 29/376,257 (File No. 066501-5008-US), filed Oct. 4, 2010, and to U.S. Design patent application Ser. No. 29/376,428 (File No. 066501-5008-US01) filed Oct. 6, 2010, entitled Case with Metal Back and Band Edge for a Cord Management System, and to U.S. Design patent application Ser. No. 29/376,430 (File No. 066501-5008-US02) filed Oct. 6, 2010, entitled Case with Metal Back and Band Edge for a Cord Management System, and to U.S. Design patent application Ser. No. 29/375,648 (File No. 066501-5007-US), entitled Case with Metal Back for a Cord Management System, filed Sep. 24, 2010, and to U.S. Design patent application Ser. No. 29/375,649 (File No. 066501-5007-US01) filed Sep. 24, 2010, entitled Case with Metal Back for a Cord Management System, and to U.S. Design patent application Ser. No. 29/375,651 (File No. 066501-5007-US02) filed Sep. 24, 2010, entitled Case with Metal Back for a Cord Management System, and to U.S. Design patent application Ser. No. 29/376,041 (File No. 066501-5007-US03) filed Sep. 30, 2010, entitled Case with Metal Back for a Cord Management System, the disclosures of which are all incorporated herein by reference in their entirety.

### TECHNICAL FIELD

The disclosed embodiments relate generally to systems and methods for using accessories in connection with mobile electronic device cases.

### BACKGROUND

Many people today use portable electronic devices, such as mobile phones, audio players, video players, etc. In conjunction with these devices, many users choose to protect these expensive and often fragile devices with cases. Due to their portable size and their convenient functionality, many users carry these devices with them frequently. In addition, many people frequently find it convenient to carry other accessories with them. For instance, some people carry additional items and/or accessories, such as wallets, pocket knives, notepads, and the like (herein referred to as “accessories”). As the number of accessories that a person carries increases, the more difficult it becomes to find a convenient carrying place for each item. Furthermore, when a user carries multiple individual accessories, there is a greater likelihood that they will lose or misplace one of the items.

It would therefore be advantageous to provide systems and methods whereby a user of a portable electronic device could removably attach accessories to a case for that electronic device in order to minimize clutter, prevent loss of the accessories, and provide a convenient method of storing and transporting the accessories.

Furthermore, many additional interactive features are now being included on mobile electronic devices. For instance, many cellular telephones include large screens for displaying video, camera lenses and flashes for taking still photos or videos, and many have the processing capability and geosynchronous positioning hardware to run and display GPS (or similar) navigation programs. Thus, the same systems and methods that allow a user to removably attach an accessory (such as a notepad or a flashlight) to a mobile electronic device case could be adapted to create accessories that mount or support mobile electronic device cases in convenient positions, locations, and orientations.

It would therefore be advantageous to provide systems and methods whereby a user of a portable electronic device could removably attach a case for that electronic device to an accessory that mounts, supports, displays, and/or holds the mobile electronic device for ease of viewing or use by a user.

Thus, an accessory attachment system for portable electronic devices that solves the aforementioned problems is desirable.

### SUMMARY

Some embodiments provide a mobile electronic device accessory system. The accessory system comprises a mobile electronic device case with a surface and a first attachment mechanism, and an accessory with a second attachment mechanism. The accessory is removably attached to the surface of the mobile electronic device case. The first and second attachment mechanisms can be any of a group consisting of magnet(s); magnetic material; Velcro; adhesives; suction devices; friction mechanisms; buckles; hinges; springs; bistable springs; sleeves that insert into slots; pegs that insert into holes snaps; buttons; and a van der Waals force attachment mechanism.

In some embodiments, the second attachment mechanism comprises at least one magnet and/or magnetic material.

In some embodiments, the first attachment mechanism is at least one magnetic material component of the mobile electronic device case. In some embodiments, the first attachment mechanism is the back of a mobile electronic device case that is composed at least partially of magnetic material and/or metal. In some embodiments, the magnetic material is ferromagnetic material and/or paramagnetic material.

In some embodiments, the accessory removably attached to the mobile electronic device case is a carrying accessory, a card holder, a money clip, a coin purse, a tape measure, a key holder, a photograph holder, a flashlight, a laser pointer, a binder clip, a notepad, or a tape measure.

Some embodiments provide an accessory-holding case for a mobile electronic device, where the case is configured to hold an accessory. The case has a back, where the back has a recessed portion defined by a shoulder. The recessed portion is sized and configured to receive an accessory therein. The case also has an attachment mechanism for removably attaching the accessory to the mobile electronic device case.

Some embodiments provide an accessory that is a flat multiple tool holder for connection to a mobile electronic device case. The tool holder has a housing that is configured to fit substantially within an area defined by a surface of the mobile electronic device case. The housing defines at least one opening to receive an instrument into at least one internal chamber that is configured to enclose at least a portion of the instrument. The housing also has an attachment mechanism for removably attaching the housing to the surface of the mobile electronic device case.

Some embodiments provide a flat multi-tool with a plurality of tools in combination. The multi-tool has a peripheral outer edge that is configured to fit substantially within an area defined by a surface of a mobile electronic device case. The multi-tool also has at least one attachment mechanism attached to a first surface of the multi-tool, where the attachment mechanism allows a user to removably attach the multi-tool to a surface of a mobile electronic device case.

Some embodiments provide a flat multi-tool accessory system. The system includes a mobile electronic device case that has a back with recessed portion defined by a shoulder. The case also has a first attachment mechanism. The system includes a flat multi-tool with a plurality of tools in combination, and a peripheral outer edge configured to fit within the recess in the back of the mobile electronic device case.

Some embodiments provide a digital storage device for connection to a mobile electronic device case. The digital storage device has a body configured to fit substantially within an area defined by a surface of the mobile electronic device case. The digital storage device also has a re-programmable, non-volatile flash memory element with an interface connector for connecting the digital storage device with a computer, and an attachment mechanism connected with the body for removably attaching the digital storage device to the surface of the mobile electronic device case.

Some embodiments provide a ruler accessory, where the ruler is configured to fit substantially within an area defined by a surface of a mobile electronic device case. The ruler also has an attachment mechanism attached with the ruler for removably attaching the ruler to the surface of the mobile electronic device case.

Some embodiments provide a support accessory for supporting a mobile electronic device case. The support accessory has a support member and a magnetic attachment element attached to the support member. The magnetic attachment element allows the support accessory to be removably attached in a supporting position to a surface of the mobile electronic device case.

Some embodiments provide a support member with a mounting element hingably attached with a support member. The support member can be moved between a first collapsed position and a second operating position. The mounting element also comprises an attachment mechanism for removably attaching the support accessory to a surface of the mobile electronic device case.

Some embodiments provide a mobile device connection system. The system includes a case for a mobile electronic device, where the case has a back. The back of the case has a set of first magnetic attachment elements for removably mounting the case to a corresponding set of second magnetic attachment elements attached to an object external to the case. The back also has a first electrical interface for interfacing with a second electrical interface attached to the object external to the case. The back also has a third electrical interface attached with the case for connection to a fourth electrical interface on the mobile electronic device. The third electrical interface is electrically connected with the first electrical interface. In some embodiments, the object external to the case is a charger.

Some embodiments provide a mobile device connection system including a charger. The charger has a plug for connecting the charger to a power source, a magnetic attachment element, and a cable. The cable is attached to the charger at a first end, and has a first electrical interface at a second end apart from the first end. The first electrical interface is for connection to a mobile electronic device that has a second electrical interface. The cable and first electrical interface are configured to transmit electric current to the mobile electronic device when the first and second interfaces are brought into electrical communication.

Some embodiments provide a mobile device mounting system with a first mounting member that has a first attachment element for removably attaching the mounting device to an object, and a second mounting member with a magnetic attachment element for removably connecting a mobile electronic device case.

Some embodiments provide a mobile electronic device charger. The charger has a housing, a mounting surface with a magnetic attachment element for removably connecting a mobile electronic device case, and a plug. The plug connects the mobile electronic device charger to a power source, and is flexibly connected to the mounting device. The mounting surface is configured to be movable into many positions, including a position that allows the mobile electronic device to be viewable by the driver of a vehicle when the plug is connected with the electrical outlet.

Some embodiments provide a method of using an accessory for a mobile electronic device case. The method includes providing a mobile electronic device case with a surface and a first attachment mechanism. The method also includes providing an accessory with a second attachment mechanism, the accessory configured to be removably attached to a surface of the mobile electronic device case. Finally, the method includes removably attaching the accessory to the surface of the mobile electronic device case via the first and second attachment mechanisms. In some embodiments, any of the above mentioned accessories can be used in the method.

### BRIEF DESCRIPTION OF THE DRAWINGS

FIG. 1A illustrates components of a mobile electronic device case accessory system, with the accessory removed from the case, according to some embodiments.

FIG. 1B is another view of components of a mobile electronic device case accessory system, with the accessory removed from the case, according to some embodiments.

FIG. 2 illustrates components of a mobile electronic device case accessory system, with the accessory removably attached to the case, according to some embodiments.

FIG. 3 is a flow chart of a method for using a mobile electronic device case accessory system, according to some embodiments.

FIG. 4A is a front view of an accessory, according to some embodiments.

FIG. 4B is front view of the accessory of FIG. 4A, illustrating the accessory in an open configuration, according to some embodiments.

FIG. 4C is a back view of an accessory, according to some embodiments.

FIG. 5 illustrates the accessory of FIGS. 4A-C removably attached to a surface of a mobile electronic device case.

FIG. 6A is a front view of an accessory, according to some embodiments.

FIG. 6B is front view of the accessory of FIG. 6A, illustrating the accessory in an open configuration, according to some embodiments.

FIG. 6C is a back view of an accessory, according to some embodiments.

FIG. 7 illustrates the accessory of FIGS. 6A-C removably attached to a surface of a mobile electronic device case.

FIG. 8A is a front view of an accessory, according to some embodiments.

FIG. 8B is front view of the accessory of FIG. 8A, illustrating the accessory in a partly open configuration, according to some embodiments.

FIG. 8C is a sectional view of the accessory of FIG. 8A, according to some embodiments.

FIG. 8D is a back view of an accessory, according to some embodiments.

FIG. 9 illustrates the accessory of FIGS. 8A-D removably attached to a surface of a mobile electronic device case.

FIG. 10A is a front view of an accessory, according to some embodiments.

FIG. 10B is a back view of an accessory, according to some embodiments.

FIG. 11 illustrates the accessory of FIGS. 10A-B removably attached to a surface of a mobile electronic device case.

FIG. 12A is a front view of an accessory, according to some embodiments.

FIG. 12B is a partial sectional view of the accessory of FIG. 12A, according to some embodiments.

FIG. 12C is a back view of an accessory, according to some embodiments.

FIG. 13 illustrates the accessory of FIGS. 12A-C removably attached to a surface of a mobile electronic device case.

FIG. 14 is a front view of an accessory, according to some embodiments.

FIG. 15A is a front view of an accessory, according to some embodiments.

FIG. 15B is a back view of an accessory, according to some embodiments.

FIG. 16 illustrates the accessory of FIGS. 15A-B removably attached to a surface of a mobile electronic device case.

FIG. 17A is a front view of an accessory, according to some embodiments.

FIG. 17B is a back view of an accessory, according to some embodiments.

FIG. 18 illustrates the accessory of FIGS. 17A-B removably attached to a surface of a mobile electronic device case.

FIG. 19A is a front view of an accessory, according to some embodiments.

FIG. 19B is a back view of an accessory, according to some embodiments.

FIG. 20 illustrates the accessory of FIGS. 19A-B removably attached to a surface of a mobile electronic device case.

FIG. 21A is a front view of an accessory, according to some embodiments.

FIG. 21B is a back view of an accessory, according to some embodiments.

FIG. 22 illustrates the accessory of FIGS. 21A-B removably attached to a surface of a mobile electronic device case.

FIG. 23 is a front view of an accessory, according to some embodiments.

FIG. 24 illustrates the accessory of FIG. 23 removably attached to a surface of a mobile electronic device case.

FIG. 25 is a front view of an accessory, according to some embodiments.

FIG. 26 illustrates the accessory of FIG. 25 removably attached to a surface of a mobile electronic device case.

FIG. 27A is a front view of an accessory, according to some embodiments.

FIG. 27B is a back view of an accessory, according to some embodiments.

FIG. 28 illustrates the accessory of FIGS. 27A-B removably attached to a surface of a mobile electronic device case.

FIG. 29A is a front view of an accessory, according to some embodiments.

FIG. 29B is another front view of the accessory of FIG. 29A, illustrating the accessory in an open position, according to some embodiments.

FIG. 29C is a back view of an accessory, according to some embodiments.

FIG. 30 illustrates the accessory of FIGS. 29A-C removably attached to a surface of a mobile electronic device case.

FIG. 31A is a front view of an accessory, according to some embodiments.

FIG. 31B is a back view of an accessory, according to some embodiments.

FIG. 32 illustrates the accessory of FIGS. 31A-B removably attached to a surface of a mobile electronic device case.

FIG. 33A is a front view of an accessory, according to some embodiments.

FIG. 33B is a side view of an accessory, according to some embodiments.

FIG. 33C is a back view of an accessory, according to some embodiments.

FIG. 33D is a side view of an accessory, according to some embodiments.

FIG. 34A illustrates the accessory of FIGS. 33A-C removably attached to a surface of a mobile electronic device case.

FIG. 34B illustrates the accessory of FIG. 33D removed from a surface of a mobile electronic device case.

FIG. 35A is a front view of an accessory, according to some embodiments.

FIG. 35B is a back view of an accessory, according to some embodiments.

FIG. 35C is another front view of an accessory, according to some embodiments.

FIG. 36 is a front view of an accessory, according to some embodiments.

FIG. 37A is a front view of an accessory, according to some embodiments.

FIG. 37B is a back view of an accessory, according to some embodiments.

FIG. 38A illustrates the accessory of FIGS. 37A-B in conjunction with a mobile electronic device case, according to some embodiments.

FIG. 38B illustrates the accessory of FIGS. 37A-B removably attached to a mobile electronic device case, according to some embodiments.

FIG. 39 is an end view of the accessory of FIGS. 37A-B, according to some embodiments.

FIG. 40 is an end view of the accessory of FIGS. 37A-B, according to some embodiments.

FIG. 41A is a front view of an accessory, according to some embodiments.

FIG. 41B is a back view of an accessory, according to some embodiments.

FIG. 42 illustrates the accessory of FIGS. 41A-B removably attached to a surface of a mobile electronic device case.

FIG. 43A is a front view of an accessory, according to some embodiments.

FIG. 43B is a back view of an accessory, according to some embodiments.

FIG. 44 illustrates the accessory of FIGS. 43A-B removably attached to a surface of a mobile electronic device case.

FIG. 45 is a partial sectional view of the accessory of FIG. 43, according to some embodiments.

FIG. 46A is a front view of an accessory, according to some embodiments.

FIG. 46B is a back view of an accessory, according to some embodiments.

FIG. 46C is a perspective view of the accessory of FIG. 46A in a partially open position.

FIG. 47 illustrates the accessory of FIGS. 46A-C removably attached to a surface of a mobile electronic device case.

FIG. 48A is a front view of an accessory, according to some embodiments.

FIG. 48B is a back view of an accessory, according to some embodiments.

FIG. 49 illustrates the accessory of FIGS. 48A-B removably attached to a surface of a mobile electronic device case.

FIG. 50A is a front view of an accessory, according to some embodiments.

FIG. 50B is a back view of an accessory, according to some embodiments.

FIG. 51 illustrates the accessory of FIGS. 50A-B removably attached to a surface of a mobile electronic device case.

FIG. 52A illustrates the accessory of FIGS. 50A-B supporting a mobile electronic device case.

FIG. 52B illustrates the accessory of FIGS. 50A-B supporting a mobile electronic device case in an alternative position.

FIG. 53A is a front view of an accessory, showing the accessory in an open position, according to some embodiments.

FIG. 53B is a back view of an accessory, showing the accessory in a closed position, according to some embodiments.

FIG. 53C is an exploded view of a portion of the accessory of FIGS. 53A-B, according to some embodiments.

FIG. 54A illustrates the accessory of FIGS. 53A-C supporting a mobile electronic device case.

FIG. 54B illustrates the accessory of FIGS. 53A-C supporting a mobile electronic device case in an alternative position.

FIG. 55A is a front view of an accessory, according to some embodiments.

FIG. 55B is a back view of an accessory, according to some embodiments.

FIG. 56 illustrates the accessory of FIGS. 55A-B supporting a mobile electronic device case.

FIG. 57 illustrates components of a magnetically attached mounting accessory system, with the accessory removed from the case, according to some embodiments.

FIG. 58 is a front view of a case for a magnetically attached mounting accessory system, according to some embodiments.

FIG. 59A is a front view of an object for mounting to a case, according to some embodiments.

FIG. 59B is a back view of an object for mounting to a case, according to some embodiments.

FIG. 59C is a back view of an object for mounting to a case, according to some embodiments.

FIG. 59D is a back view of an object for mounting to a case, according to some embodiments.

FIG. 60A is a front view of an object for mounting to a case, according to some embodiments.

FIG. 60B is a back view of an object for mounting to a case, according to some embodiments.

FIG. 61A illustrates components of a magnetically attached mounting system, with the object for mounting to a case removably attached to the case, according to some embodiments.

FIG. 61B illustrates components of a magnetically attached mounting system, with the object for mounting to a case removed from the case, according to some embodiments.

FIG. 62A is a front view of an object for mounting to a case, according to some embodiments.

FIG. 62B is a back view of an object for mounting to a case, according to some embodiments.

FIG. 63 illustrates the components of a magnetically attached mounting system, with the case removed from the mounting object.

FIG. 64A illustrates the components of a magnetically attached mounting system, with the case removed from the mounting object.

FIG. 64B is a back view of the mounting object of FIG. 64A.

FIG. 65A illustrates the components of a magnetically attached mounting system, with the case removed from the mounting object.

FIG. 65B is a back view of the mounting object of FIG. 65A.

Like reference numerals refer to corresponding parts throughout the drawings.

### DESCRIPTION OF EMBODIMENTS

### Accessory System

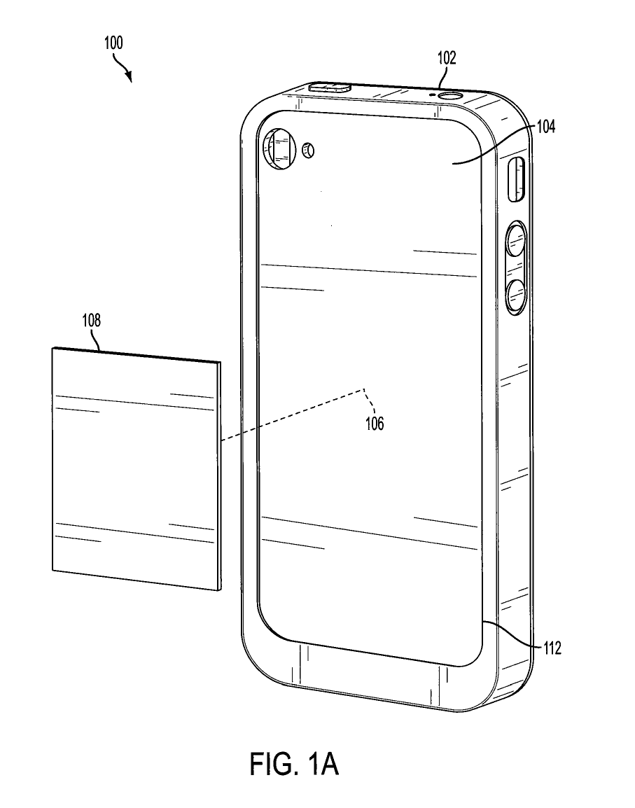

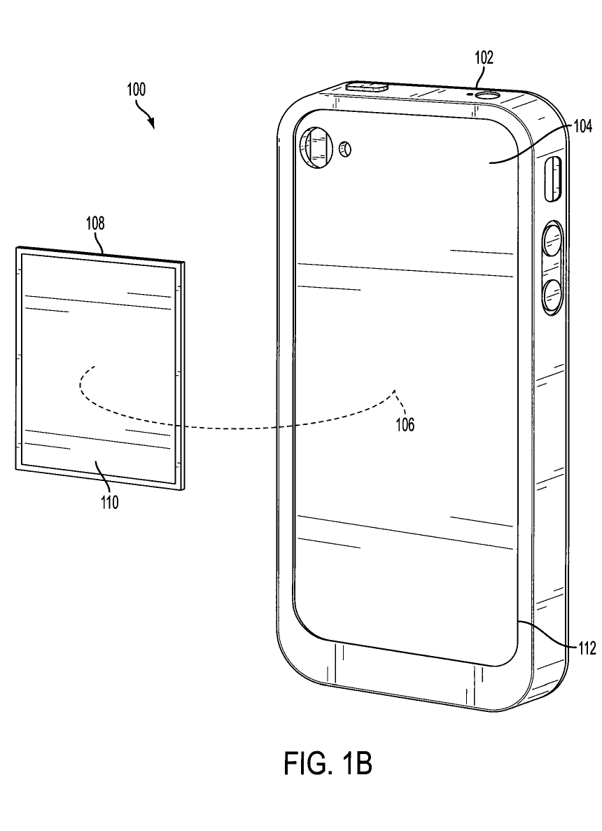

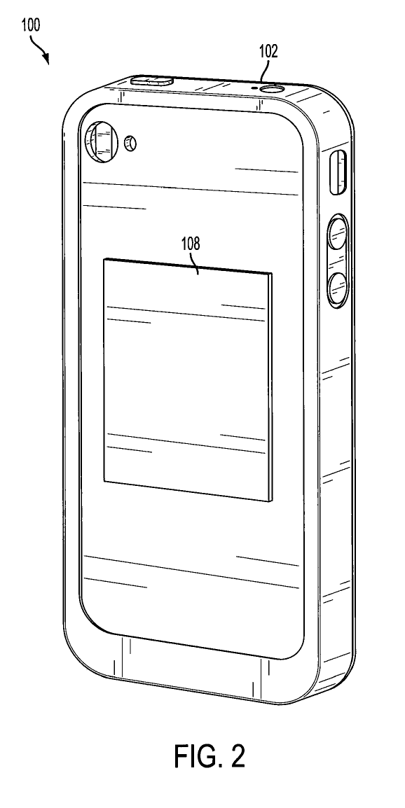

To address the aforementioned problems, some embodiments provide a mobile electronic device accessory system. FIGS. 1 and 2 illustrate components of an exemplary accessory system 100. The components of the system may include a case 102 for a mobile electronic device, where the case 102 has a surface 104 and a first attachment mechanism 106. The system may also include an accessory 108 with a second attachment mechanism 110. The accessory 108 can be removably connected with the surface 104 of the case 102. Particular embodiments of the accessory 108 are described in more detail through the remainder of the specification.

It may be inconvenient to users of an accessory system as described in the present application if portions of an accessory were to protrude from the outer edges of their mobile electronics device case. In some embodiments, the accessory 108 is configured to fit substantially within an area defined by the surface 104. In some embodiments, the accessory 108 can be configured to fit completely within the surface 104. Furthermore, in some embodiments, the accessory 108 is thinner than the thickness of the case 102. These embodiments minimize the overall size of the accessory system to ensure that attachment of an accessory to a mobile electronic device case is not cumbersome for a user.

In some embodiments, the case 102 is configured to fit over a mobile electronic device case that is approximately 4.5 inches tall, 2.31 inches wide, and 0.37 inches thick. Accordingly, a case 102 designed for a device of these dimensions will have a surface 104 of similar height and width, accounting for the slight increase in the size of the case 102 necessary due to the material of the case. Similarly, in embodiments where the accessory 108 is designed to be thinner than the thickness of the case 102, the accessory 108 may be no thicker than 0.37 inches. In some embodiments, however, the accessory 108 is thinner or thicker than 0.37 inches, depending on design considerations and constraints on the type of accessory. While the system described in the present application refers to cases for mobile electronic devices, the same principles and disclosures can be applied directly to the structure (e.g., the housing) of a mobile electronic device, or even to a case for another type of device or object. Such modifications are within the spirit and the scope of the present disclosure.

In some embodiments, the accessory 108 is used with a mobile electronic device case where the back surface 104 of the case has a recessed portion defined by a shoulder or raised edge 112. As shown in FIG. 1, the main portion of the back surface 104 of the case 102 is recessed with respect to the raised edge 112. In some embodiments, the accessory 108 is thinner than, or the same thickness as, the recess between the back surface 104 and the raised edge 112. Thus, when the accessory 108 is attached to the back surface 104 of the case 102, the accessory 108 does not protrude any further than the outer surfaces of the case 102. In some embodiments, the accessory 108 is thicker than the recess. In some embodiments, the accessory 108 protrudes further than the outer surfaces of the case 102 by only half as much as the recess.

In some embodiments, a case can include accessory alignment mechanisms, such as recesses configured to receive corresponding protrusions on the accessories, and/or discrete magnetic attachment elements, such as individual magnetic disks, that are configured to mate to corresponding magnetic attachment elements on an accessory. Such corresponding alignment mechanisms can be used to help ensure that accessories are placed in a consistent location on the case each time the user attaches an accessory to the case.

In some embodiments, polarities of magnets can be additionally or alternatively used to help ensure alignment. For example, in some embodiments, an accessory includes two discrete magnetic attachment elements, each presenting opposite polarities to its attachment surface. Likewise, a case can include two corresponding discrete magnetic attachment elements, each presenting opposite polarities to its attachment surface. Thus, when a user attempts to attach the accessory to the surface of the case, the accessory will only be attracted to the case when the respective discrete magnetic attachment elements present opposite polarities to one another. Otherwise, if the respective discrete magnetic attachment elements present the same polarities to one another, the accessory will be repelled from the case and the accessory will not adhere to the case. It is noted that many different arrangements of magnetic attachment elements can be used to exploit the attractive and repulsive properties of magnets. One of skill in the art will recognize that many arrangements are possible without departing from the spirit of the invention.

In some embodiments, the first attachment mechanism 106 and the second attachment mechanism 110 use magnets and/or magnetic materials to removably attach the accessory 108 to the case 102. In some embodiments, the first attachment mechanism 106 is a magnetic material, and the second attachment mechanism 110 is a magnet, magnets, and/or magnetic material(s). The magnets may include any element or composition that is capable of producing a magnetic field. For example, the magnets may include one or more of magnetic metallic elements (e.g., iron, cobalt, nickel, etc.), composite magnets (e.g., ceramic or ferrite magnets, alnico magnets, ticonal magnets, injection molded magnets, flexible magnets), rare earth magnets (e.g., samarium-cobalt magnets, neodymium-iron-boron magnets, etc.), electromagnets, sets of any of these magnets, or any other material or composition that produces a magnetic field. In some embodiments, the magnets are neodymium magnets. In some embodiments, the neodymium magnets are a grade N42. In some embodiments, the magnets are solid magnets. In some embodiments, the magnets are selected from the group consisting of donut (ring) magnets, horseshoe-shaped (U-shaped) magnets, cylindrical magnets, disc-shaped magnets, cuboid-shaped magnets, and the like. While any magnet may be described as a singular magnet, it should be recognized that a “magnet” as used in the present specification may consist of more than one magnet. In some embodiments, the magnets are sets of magnets. The selection of the size, shape, and number of the magnets may depend on factors including, but not limited to, a desired magnetic strength, a desired form factor, and a desired aesthetic. It should be noted that when a magnetic attachment system as described above is used, is to be understood that the any of the first or second attachment mechanisms 106, 110, or any magnetic attachment element, can use magnets and/or magnetic material(s). Thus, it does not matter whether the first or second attachment mechanism is a magnet and/or magnetic material(s), respectively, so long as the attachment mechanisms are magnetically attracted to one another.

In some embodiments, the first attachment mechanism 106 is the back of a case, where the back is made at least partially of a magnet or magnetic material, referred to herein as a magnetic material back. The magnetic material back can be made of any magnetic material and/or paramagnetic material. In some embodiments, the magnetic material is a magnet, as described above. In some embodiments, the magnetic material is metal. Metals that respond sufficiently to magnetic fields such that magnets may adhere to them are referred to herein as “magnetic metals.” In some embodiments, the magnetic material is low-carbon steel. In some embodiments, the magnetic material is vanadium carbonyl. In some embodiments, the magnetic material back is made of a pliable material such as rubber, silicone, an elastomer (e.g., thermoplastic elastomer), or other pliable materials discussed above, wherein the pliable material encapsulates small magnets or magnetic material elements within it. For example, in some embodiments the back is made of an elastomer or paint with iron, metal, or other similar flecks in it. Furthermore, in some embodiments only a portion of the back of the case includes the magnet or magnetic material. For example, in alternative embodiments such a partial magnetic material back covers only three-quarters, half, one quarter, or less of the back of the object. In some embodiments, the magnetic material back may include individual magnetic material elements contained in or on the magnetic material back. For the purpose of simplicity throughout the present application, we refer to all such magnetic material backs and partial magnetic material backs as “magnetic material backs.” It should also be noted that the connection mechanisms described herein with reference to the mobile electronic device case equally apply to mobile electronic devices as well, or any portion or surface of a mobile electronic device.

Note that although a magnet may be considered a magnetic material, a magnetic material is not necessarily a magnet. Specifically, a magnetic material is a material or composition that produces a magnetic field in response to an applied magnetic field (e.g., a magnetic field produced by a magnet). The magnetic material may include one or more of a ferromagnetic material and a paramagnetic material.

In the present application, a “magnetic” component may refer equally to a magnet or a magnetic material. It is well known that a magnet of sufficient magnetic strength will adhere to certain magnetic materials. Thus, a magnetic attachment system can use a magnet on one component and a magnetic material on another component to achieve adhesion between the components. It is to be understood in the present application that the particular placement of a magnet or a magnetic material on two components can be inverted. For example, a mobile electronic device case could include a magnetic material back (such as a magnetic metal back), to which accessories with magnets are removably attached. Equivalently, a case could include a magnet for at least a portion of the back, to which accessories with magnetic material (such as magnetic metal) portions can be removably attached. Alternatively, both the accessory and the case could use magnets. Furthermore, the magnets and magnetic materials discussed herein refer only to those materials that are capable of producing an adhesive force between them that is sufficient to attach components to one another. Materials that are commonly referred to as “non-magnetic” (those that are not or are only negligibly affected by magnetic fields) are not within the scope of the disclosure even though they may technically exhibit some nominal magnetic properties. For example, aluminum is often considered non-magnetic

A case 102 with a magnetic material back allows a user to position the accessory 108 on any portion of the magnetic material back that the user desires, like magnets on a refrigerator door. In other words, as long as the accessory 108 includes at least one magnet, the accessory 108 can be placed in any position on the magnetic material back. Sometimes it will be advantageous for the accessory 108 to have a specific, determined location on the magnetic material back. Thus, in some embodiments, the magnetic material back may have additional, discrete magnetic attachment elements (comprising either magnets or magnetic materials). In some embodiments, the magnetic material back will only have discrete magnetic attachment elements. The discrete magnetic attachment elements can be configured to receive a second attachment mechanism that is made up of similarly oriented magnetic attachment elements. (Other alignment systems as described elsewhere in the specification may be alternatively or additionally be employed as well, such as those employing recesses, protrusions, and/or magnetic polarity.) As noted above, however, one of skill in the art will recognize that any combination of magnets, metals, or magnetic materials can be advantageously employed in different configurations (e.g., magnets and portions of metal can be swapped for one another) without departing from the spirit of the invention.

Also, while the first and second attachment mechanisms 106, 110 are described as magnetic attachment mechanisms, other attachment mechanisms are also envisioned. In other embodiments, snaps, hook and loop mechanisms, Velcro, adhesives, magnetic beads, suction devices, van der Waals force attachment mechanisms, buttons, buckles, springs, sleeves that insert into slots, pegs that are inserted into holes, hinges, and snaps may be used. For example, in some embodiments, a hook portion of a Velcro attachment is provided at the first attachment mechanism 106, while a loop portion of a Velcro attachment point is provided at the second attachment mechanism 110 (or vice versa). When the two attachment mechanisms are brought into contact with one another, they will hold the accessory 108 to the surface of the case 102 as shown in FIG. 2. It should be noted that the foregoing descriptions of attachment mechanisms, magnets, magnetic materials, and metal surfaces apply equally to all of the attachment mechanisms described below with reference to embodiments of the accessory 108.

FIG. 2 illustrates the accessory 108 removably attached to a mobile electronic device case 102.

A case as used and described herein can be configured to hold a mobile electronic device in many different configurations. In some embodiments, the case at least partially surrounds 5 sides of a mobile electronic device. In some embodiments, only a front screen surface of a mobile electronic device is substantially un-covered by the case. Of course, more or less of the mobile electronic device can be covered by a case as described in the present application. Accordingly, a case can be configured to receive a mobile electronic device without the necessity of changing or altering the device in any way. In some embodiments, the case is a protective case or shell for a mobile electronic device. Cases in accordance with embodiments of the present invention are disclosed and described in related application PCT Patent Application No. PCT/US2010/053244, entitled “Cord Management System.”

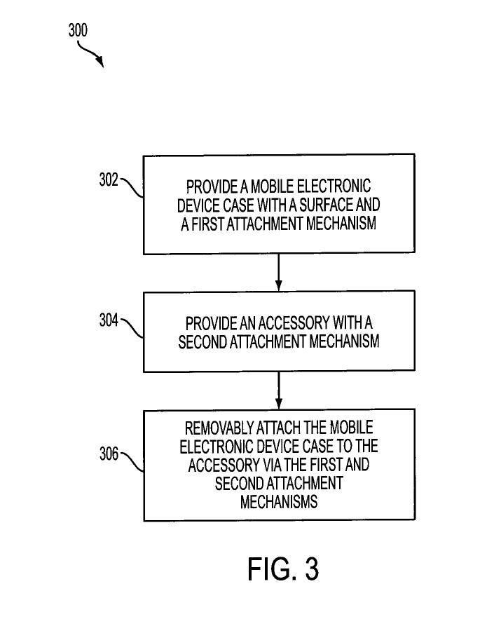

FIG. 3 is a flowchart of a method 300 for using an accessory system for a mobile electronic device case, according to some embodiments. A mobile electronic device case with a surface and a first attachment mechanism is provided (302). An accessory with a second attachment mechanism is provided (304). The accessory is removably attached (306) to the surface of the mobile electronic device case via the first and second attachment mechanisms. It should be noted that the attaching step can be alternatively stated as the mobile electronic device case being removably attached to the accessory.

The foregoing discussion relates generically to the mobile electronic device accessory system, and to general embodiments of the methods and systems for removably attaching accessories to a mobile electronic device case. Attention is now turned to specific embodiments of the accessory 108.

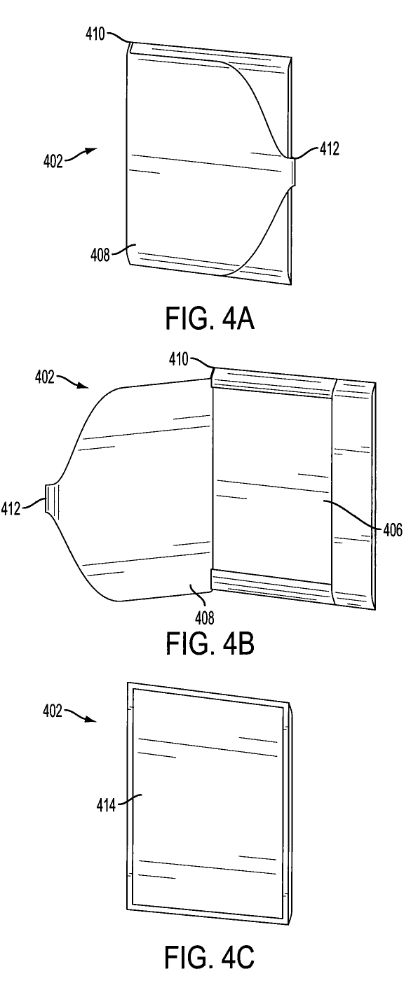

FIGS. 4-13 illustrate various embodiments where the accessory 108 is a carrying accessory. The carrying accessory can be configured to hold or carry many different types of items, and can be configured to at least partially contain at least one item or many items. As further described below with reference to specific embodiments, the carrying accessory can include numerous different holding mechanisms, including lids, covers, clips, tabs, envelopes, pockets, purses, slots, or sleeves, or any combination of these holding mechanisms.

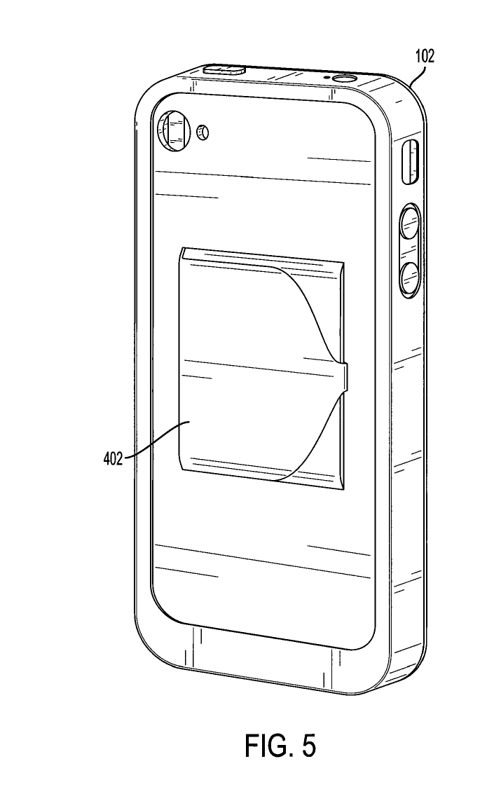

FIGS. 4 and 5 illustrate a carrying accessory that is a card holder 402. In some embodiments, the card holder 402 includes an attachment mechanism 412, a rectangular chamber 406 for holding one or more cards, and a lid 408 attached to the chamber by a hinge 410. The card holder 402 is designed to securely hold at least one card shaped object. One of skill in the art will recognize that the chamber 406 can be sized to hold many different sized cards, and many different types of card. For example, the card holder 402 could hold one or more of a drivers' license, a credit card, a debit card, an identification card, a bus card, a metro card, a business card, a gift card, a photograph, a card-sized multi-tool, a frequent-flyer card, and/or any other card-shaped object. Further, the chamber 406 can be sufficiently deep such that a plurality of cards can be contained therein. It should be noted that though the card holder 402 may be configured specifically to hold cards, the card holder 402 may conveniently hold other items as well, including keys, paper money, coins, band-aids, etc. In some embodiments, the lid 408 has an attachment mechanism 412 to maintain the lid 408 in a closed position. The attachment mechanism can be a clip, as shown in FIGS. 4-6, a friction mechanism, or any other attachment mechanism described above with reference to FIG. 1.

In some embodiments, the lid 408 is attached to the chamber 406 by a mechanism or material other than a hinge, including flexible materials, semi-flexible materials, bistable springs, metals, fabrics, leather, or any other mechanism or material capable of attaching the lid 408 to the chamber 406. In some embodiments, the card holder does not have a lid 408 or a hinge 410 at all, such as single-piece designs where the card holder has a flap portion to keep the contents in the chamber 406. In some embodiments, the cards are held in the chamber 406 by an alternative holding mechanism, including any of springs, tabs, plates, straps, cords, cables, and the like.

In some embodiments, the components of the card holder 402 are made of any suitable material or combination of materials, including, but not limited to, leather, plastic, elastomer, silicone, wood, metal, fabric, fiberglass, polymer, and/or rubber. The specific material or materials used may depend on the particular design chosen for the components of the card holder 402, and such design choices can be made without departing from the spirit of the invention.

FIG. 5 illustrates the card holder 402 removably attached to a mobile electronic device case 102.

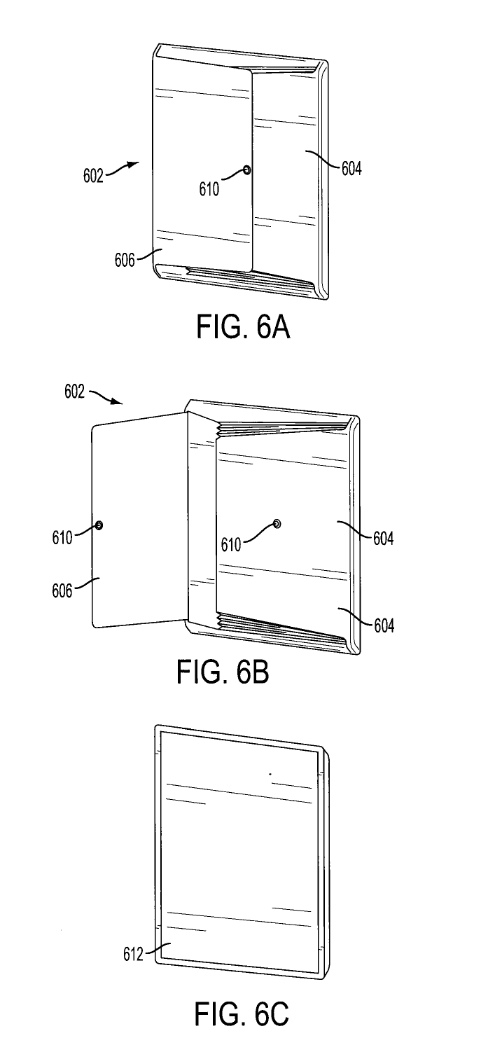

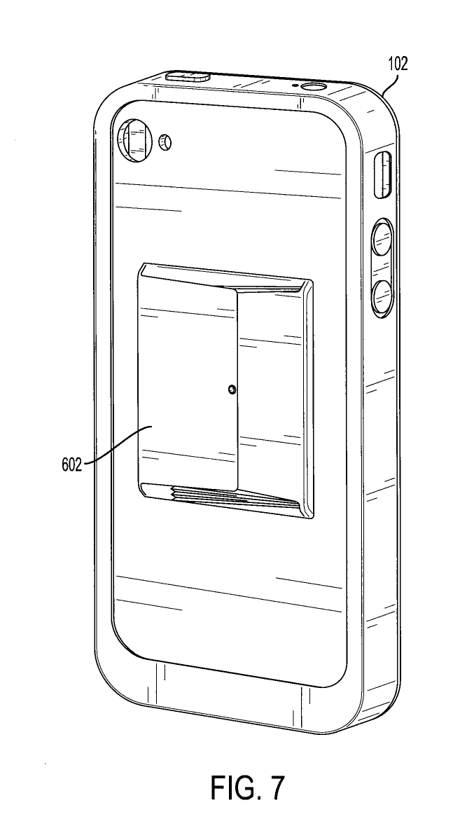

FIGS. 6 and 7 illustrate a carrying accessory that is a coin purse 602. In some embodiments, the coin purse 602 resembles an envelope, having a body 604, a cover 606, and an attachment mechanism 612. In some embodiments, the cover 606 and the body 604 are the same component, or are continuously formed. In some embodiments, the coin purse 602 includes a securing mechanism 610 to keep the cover 606 securely attached to the body 604, such that coins or other items can be held securely in the internal chamber of the body 604 when the cover 606 is closed. In some embodiments, the coin purse 602 is a squeeze type coin purse. One of skill in the art will recognize various designs for a coin purse, which can be advantageously used without departing from the spirit of the invention.

In some embodiments, the components of the coin purse 602 are made of any suitable material or combination of materials, including, but not limited to, leather, plastic, elastomer, silicone, wood, metal, fabric, fiberglass, polymer, and/or rubber. The specific material or materials used may depend on the particular design chosen for the components of the coin purse 602, and such design choices can be made without departing from the spirit of the invention.

FIG. 7 illustrates the coin purse 602 removably attached to a mobile electronic device case 102.

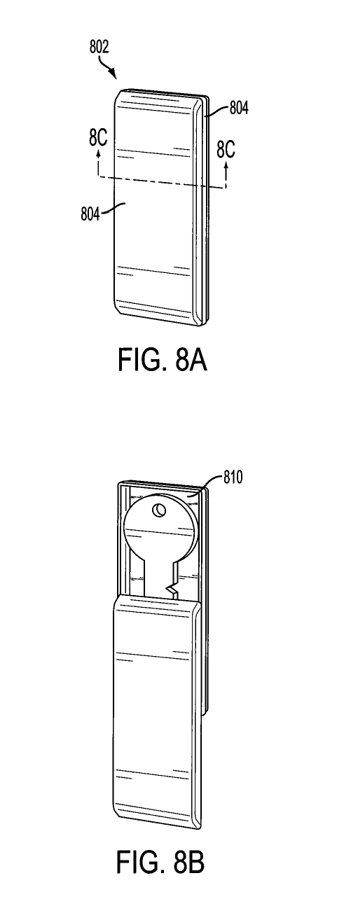

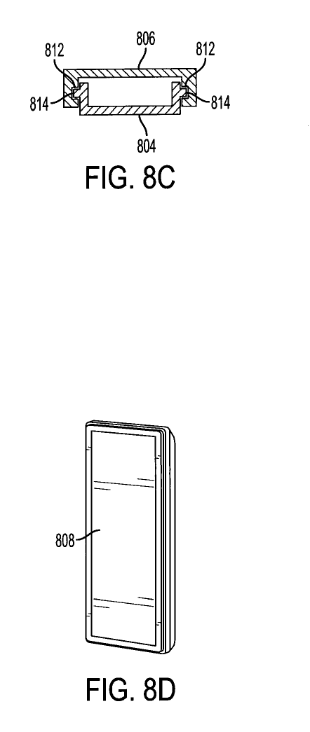

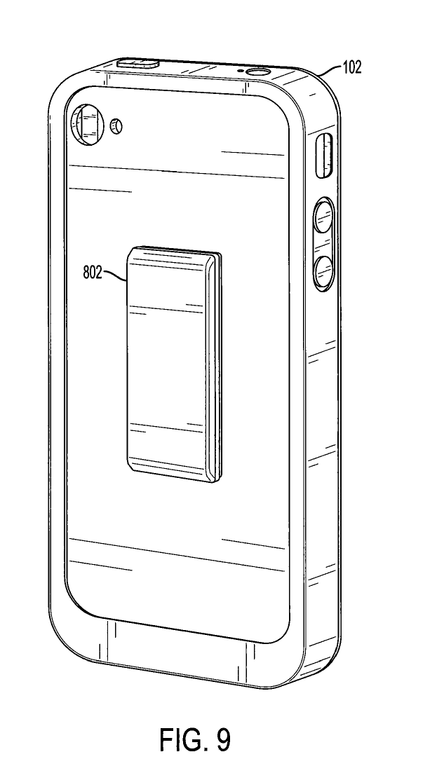

FIGS. 8 and 9 illustrate a carrying accessory that is a key holder 802. In some embodiments, the key holder 802 includes a base 804, a lid 806, and an attachment mechanism 808. The lid 806 is configured to move with respect to the base 804 in order to expose an internal chamber 810 for receiving a key. In some embodiments, as shown in FIG. 8C the lid has two channels 812 that are positioned to receive two guide tracks 814 on the base 804. The channels 812 and guide tracks 814 advantageously act to establish a sliding surface and direction between the base 804 and the lid 806. This particular configuration also provides the benefit of keeping the lid 806 captive to the base 804. In some embodiments, other lid and base configurations can be used. Furthermore, in some embodiments, the lid 806 and the base 804 can be configured to be completely separable, or connected with other connection means, including straps, hinges, etc.

In some embodiments, the components of the key holder 802 are made of any suitable material or combination of materials, including, but not limited to, leather, plastic, elastomer, silicone, wood, metal, fabric, fiberglass, polymer, and/or rubber. The specific material or materials used may depend on the particular design chosen for the key holder 802, and such design choices can be made without departing from the spirit of the invention.

In some embodiments, the key holder includes a body and at least one slot. The at least one slot defines an opening into an internal volume that is designed to receive a substantial portion of at least one key. In some embodiments, the body is a single piece of material with the slot(s) formed directly into the body. In some embodiments, the body includes multiple parts.

In some embodiments, the internal volume is sized so that when a key is inserted into the volume, a portion of the key remains exposed outside of the body, so that a user can grip the key to remove it from the body. In some embodiments, the body includes one slot, two slots, or more slots. In some embodiments, two slots are stacked on top of one another. In some embodiments, the two slots are side-by-side. In some embodiments, the body includes more than two slots, oriented with respect to each other in any way.

In some embodiments, the body, slot, or internal volume includes a retaining mechanism to keep the key securely positioned in the internal volume during storage. Any retaining mechanism can be used, including lids, straps, snaps, springs, magnets and magnetic materials, friction, van der Walls force mechanisms, and the like. In some embodiments, the body is made of a pliable material, and the slots are configured to be thinner than the thickness of a key in at least one dimension. Thus, when a key is inserted into the slot, the pliable material deforms slightly, and thereby imparts a retaining pressure on the key, preventing its inadvertent removal from the body. In some embodiments, the pliable material is rubber, elastomer, silicone, leather, fabric, coated fabric, and/or any other material.

FIG. 9 illustrates the key holder 802 removably attached to a mobile electronic device case 102.

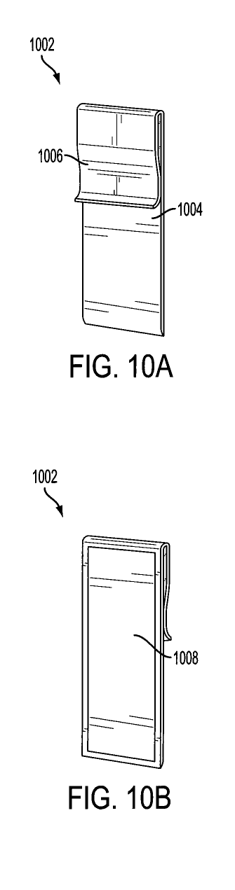

FIG. 10 illustrates a carrying accessory that is a money clip 1002. In some embodiments, the money clip 1002 is configured to hold one or more bills, checks, drivers' licenses, credit cards, debit cards, identification cards, bus cards, metro cards, business cards, gift cards, photographs, frequent-flyer cards, and/or any other sufficiently flat objects between two or more holding tines 1004 and 1006. The money clip 1002 also includes an attachment mechanism 1008. In some embodiments, the holding tines 1004, 1006 are made from a continuous piece of material. In some embodiments, the holding tines 1004, 1006 are separate structural components. In some embodiments, the money clip 1002 uses more than two holding tines. In some embodiments, a holding tine 1004 can be attached to a hinge to allow the money clip to open and close so that money or folded items can be more easily retrieved and stored in the money clip 1002. In some embodiments, a hinged tine can also include a spring mechanism to keep the spring mechanism biased in the closed position. The spring mechanism can also advantageously employ a bistable design such that the hinged tine has a stable open position and a stable closed position.

In some embodiments, the components of the money clip 1002 are made of any suitable material or combination of materials, including, but not limited to, leather, plastic, elastomer, silicone, wood, metal, fiberglass, polymer, and/or rubber. The specific material or materials used may depend on the particular design chosen for the components of the money clip 1002, and such design choices can be made without departing from the spirit of the invention.

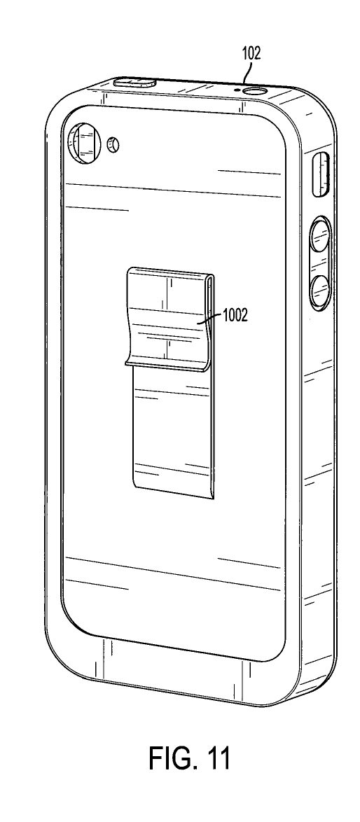

FIG. 11 illustrates the money clip 1002 removably attached to a mobile electronic device case 102.

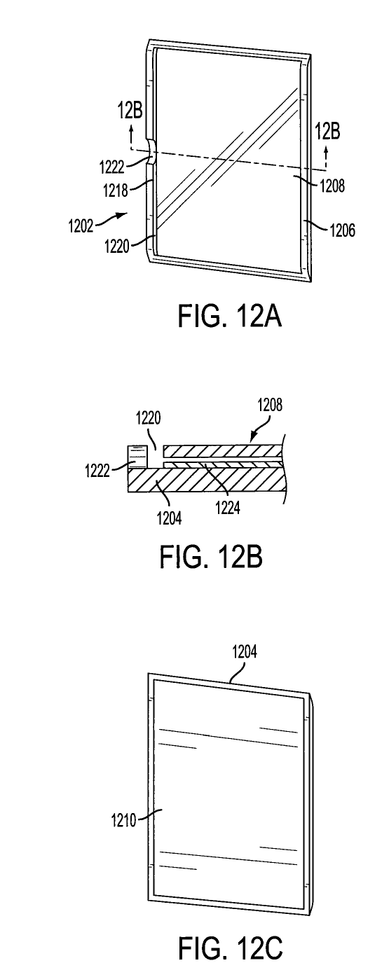

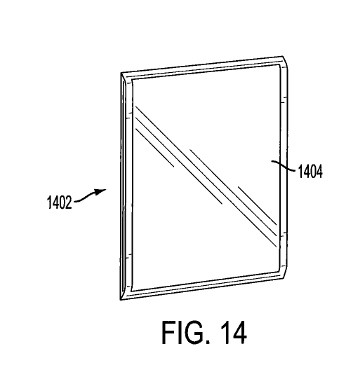

FIGS. 12-14 illustrate embodiments of a carrying accessory that is a photograph holder 1202. In some embodiments, the photograph holder 1202 has a back 1204, a front 1206, a window 1208, and an attachment mechanism 1210. In some embodiments, the front 1206 is the window 1208. In some embodiments, the window 1208 is simply an open area defined by an edge or frame that also holds a photograph in place. In some embodiments, the window 1208 is a transparent material so that a photograph can be seen there through. It is noted that the transparent material need not be completely transparent. Rather, the purpose of the window 1208 is to allow a photograph 1212 to be seen through the window 1208 by a person. Accordingly, the transparent material may be a semi-transparent, colored, clear, or any substantially see-through material, such as plastic, glass, or a composite material that is clear. The front 1206 and back 1204 of the photograph holder can be connected or formed in a variety of ways. In some embodiments, as shown in FIG. 14, the photograph holder 1402 resembles an envelope with a clear sheet front 1404. In some embodiments, as shown in FIG. 12, the photograph holder 1202 is a rigid chamber with a single opening 1214 for insertion and removal of a photograph 1224. The photograph holder can additionally include a shoulder 1218 along the opening 1220 to retain the photograph, and a finger-access cut-away 1222 to allow a user to more easily grip the photograph when inserting or removing the photograph.

While a window is described above with relation to FIGS. 12-14, it should be noted that any of the carrying accessories could optionally contain a window as described above. Furthermore, while the accessory is described as a photograph holder, it is also capable of holding any appropriately sized object. For instance, the photograph holder could be used to hold a business card, an identification card, an address card, a drivers' license, etc.

In some embodiments, the components of the photograph holder 1202 are made of any suitable material or combination of materials, including, but not limited to, leather, plastic, elastomer, silicone, wood, metal, fabric, fiberglass, polymer, and/or rubber. It is noted that window should only be made from a clear material as described above (or the window should be made with no material at all). The specific material or materials used may depend on the particular design chosen for the components of the photograph holder 1202, and such design choices can be made without departing from the spirit of the invention.

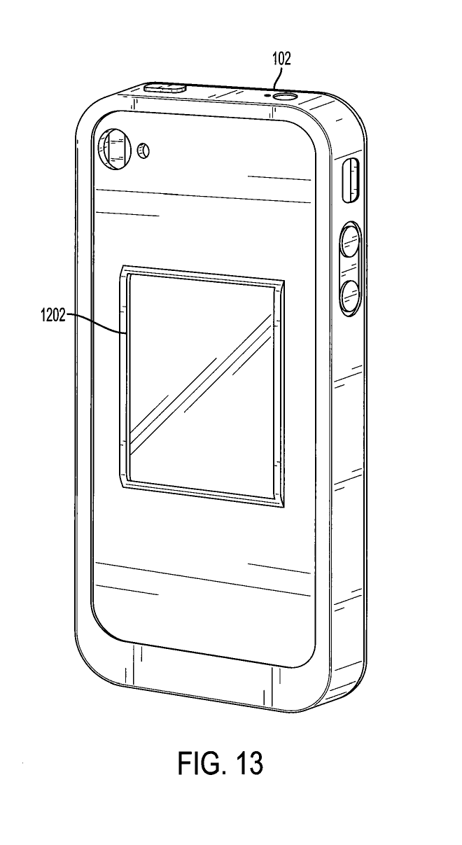

FIG. 13 illustrates an embodiment of the photograph holder 1202 removably attached to a mobile electronic device case 102.

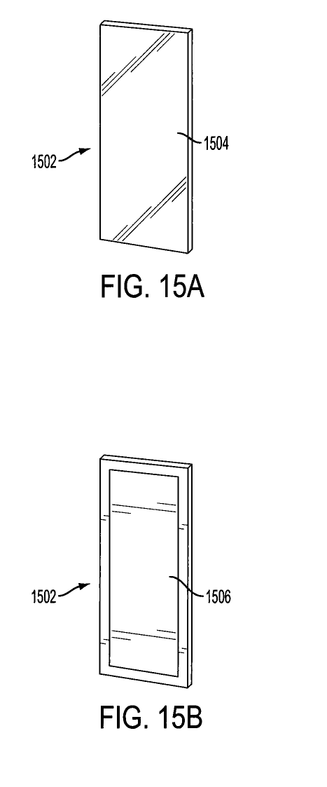

FIG. 15 illustrates an embodiment where the accessory is a mirror. The Mirror 1502 includes a front reflective side 1504 that is suited to reflecting a visible image for a person to see. The mirror 1502 also includes a back side with an attachment mechanism 1506 for removably connecting the mirror 1502 to the surface of a mobile electronic device case 102.

In some embodiments, the mirror 1502 is made of any suitable material or combination of materials, including, but not limited to, plastic, metal, fiberglass, or polymer. One of skill in the art will recognize that the mirror 1502 may be made of multiple components, such as a substrate and a reflective surface. For example, a mirror could be manufactured with a flat sheet of acrylic as a substrate with a reflective film attached to a surface of the acrylic sheet. In some embodiments, the reflective surface is a coating that is applied to the substrate, such as aluminum or silver. In some embodiments, the reflective surface is on top of the substrate (i.e., facing out from the case 102 when the mirror 15 is attached to the case). In some embodiments, the reflective surface is behind the substrate (i.e., between the substrate and the attachment mechanism). In some embodiments, the mirror is composed of only one component, such as a polished metal or plastic that is capable of reflecting an image to a user. The specific material or materials used may depend on the particular design chosen for the components of the mirror 1502, and such design choices can be made without departing from the spirit of the invention.

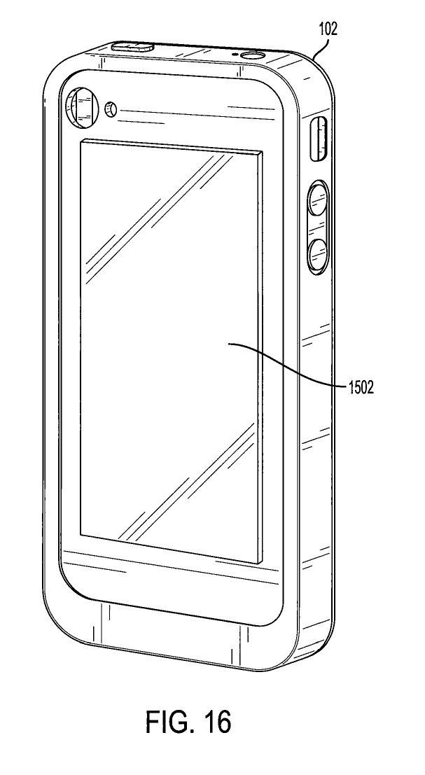

FIG. 16 illustrates the mirror 1502 removably attached to a mobile electronic device case 102.

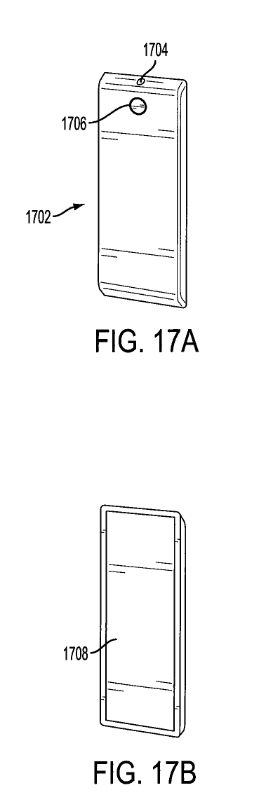

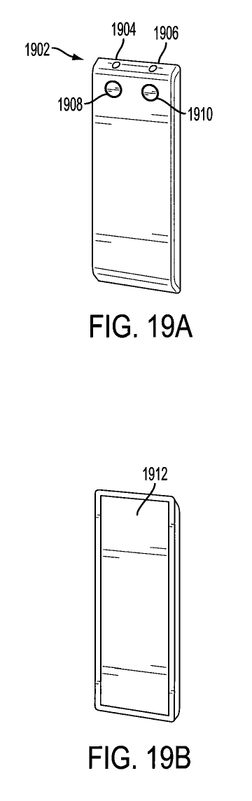

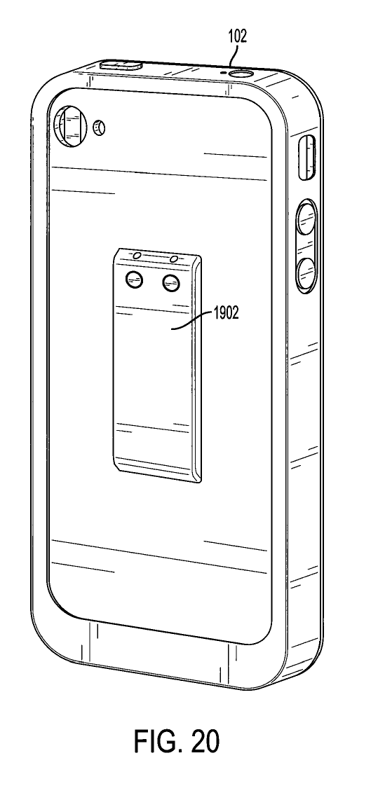

FIGS. 17-20 illustrate embodiments where the accessory is a flashlight. The flashlight 1702 includes a light source 1704, a power button 1706 or switch, a power source (such as a battery), and an attachment mechanism 1708. In some embodiments, the light source 1704 is a light emitting diode, an incandescent light bulb, or a laser. In some embodiments, the flashlight has an additional light source. For instance a flashlight could include both an LED light source and a laser light source. FIGS. 19 and 20 illustrate an embodiment of a flashlight 1902 that has two light sources, 1904, 1906, two power buttons 1908, 1910, and an attachment mechanism 1912.

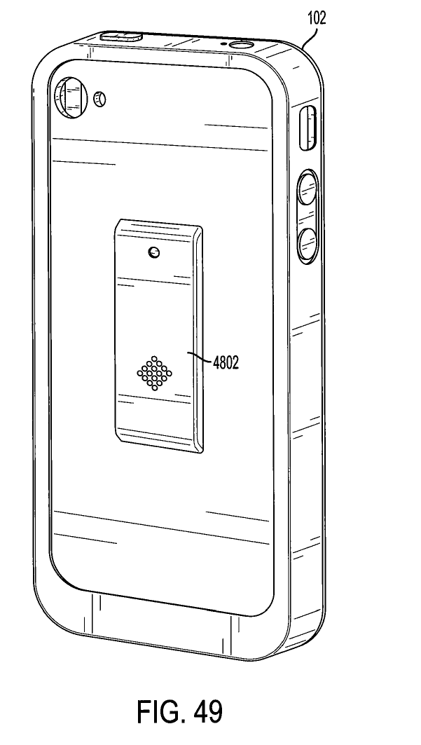

In some embodiments, the battery is removable from the flashlight 1702 so that it can be replaced. In some embodiments, the battery is a rechargeable battery that can be recharged while it is still in the flashlight. In some embodiments, the flashlight has a first electrical interface similar to that described below with reference to FIG. 49 (e.g., first electrical interface 4910 for interfacing with a second electrical interface 4912 attached to the object 4908 external to the case), so the flashlight battery can be recharged using the same charger that is configured to charge the mobile electronic device that is contained in the case 4902.

The flashlight 1702, 1902 can be used while it is attached to the mobile electronic device case 102, or it can be removed from the case 102 during use. Furthermore, the light sources 1704, 1904, and 1906 can be configured to be positioned relative to the case 102 such that the case 102 does not interfere with the light that they emit. For instance, the LED or laser light source can be spaced far enough away from the back surface 104 of the case 102 that the beams are not substantially blocked by the case. In some embodiments, the LED or laser light sources are pointed away from the surface 104 so that the case does not block the light.

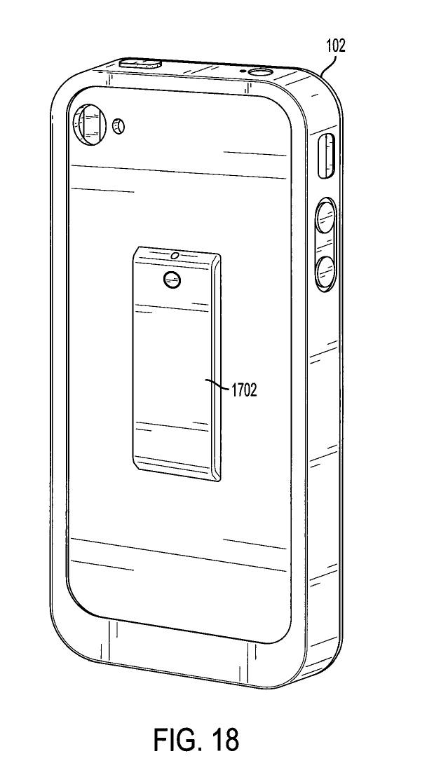

FIGS. 18 and 20 illustrate embodiments of the flashlight 1702, 1902 removably attached to a mobile electronic device case 102.

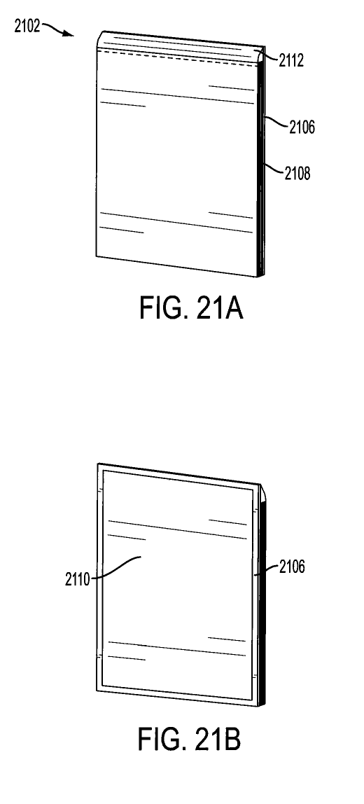

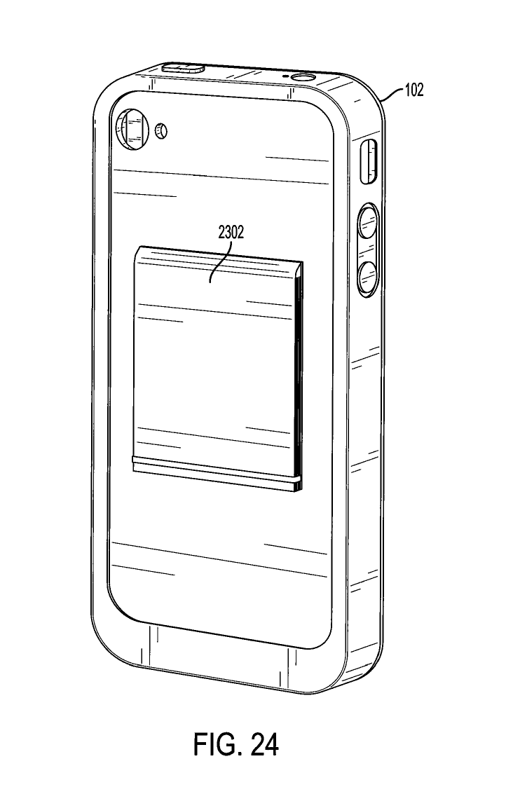

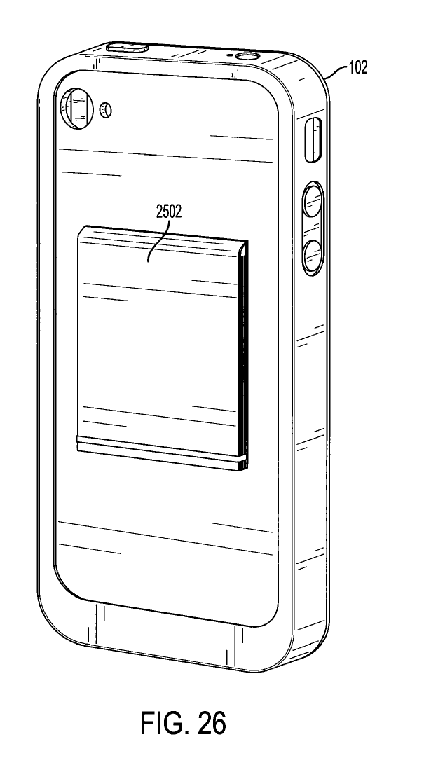

FIGS. 21-26 illustrate embodiments where the accessory is a notepad 2102. In some embodiments, the notepad 2102 includes a mounting surface 2106, a plurality of pages 2108, and an attachment mechanism 2110. In some embodiments, the plurality of pages 2108 are connected to the mounting surface 2106 with a binding 2112. In some embodiments, the binding 2112 is at the top of the notepad 2102, as shown in FIGS. 21-26. In some embodiments, the binding is at the side of the notepad.

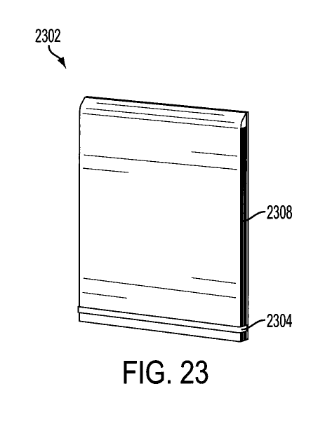

As shown in FIG. 23, in some embodiments, the notepad 2302 includes a strap 2304 connected with the mounting surface 2306 that can wrap around a portion of the plurality of pages 2308. The strap 2304 can be made of elastomer, elastic, fabric, rubber, plastic, or any other material. The strap can also be any flap, strip, pocket, tab, and/or band that can hold down the pages. When the strap 2304 is wrapped around the plurality of pages 2308, it will serve to retain the pages in a secure, flat position such that the pages 2308 are less likely to be torn or removed from the notepad 2302 when the mobile electronic device case 102 (to which the notepad is attached) is transported or stored by a user.

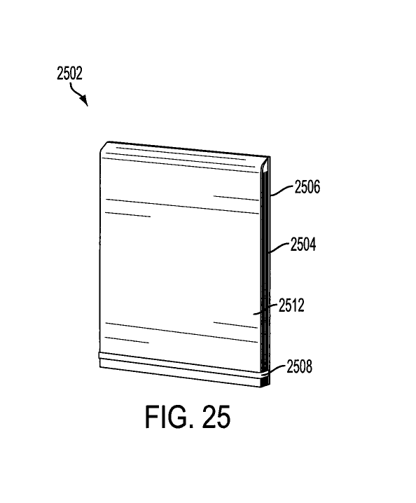

FIG. 25 shows an embodiment where the notepad 2502 includes a semi-rigid cover 2512 attached to the mounting surface 2506. In some embodiments, the notepad 2502 has a strap 2508, so the strap 2504 retains the cover 2512 as well as the pages 2504.

In some embodiments, the notepad (2102, 2302, or 2502) is configured to fit substantially within an area defined by the surface 104. In some embodiments, the notepad can be configured to fit completely within the surface 104. In some embodiments, the notepad is less than 3 inches wide. In some embodiments, the notepad is less than 2 inches wide. In some embodiments, the notepad is less than 1 inch wide.

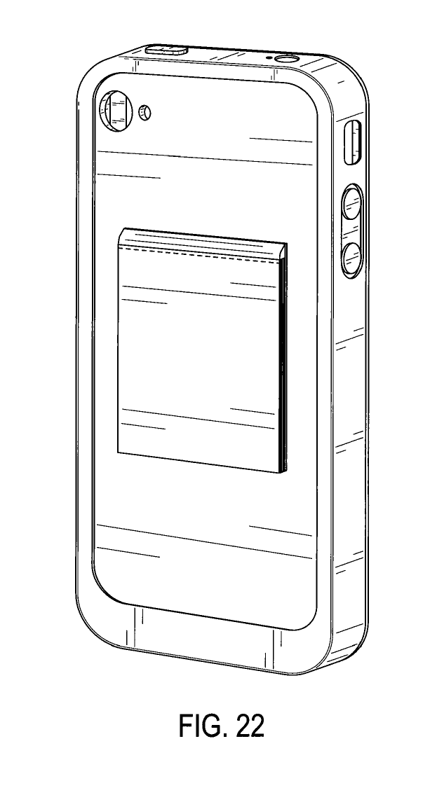

FIGS. 22, 24, and 26 illustrate embodiments of the notepad 2102, 2302, 2502 removably attached to a mobile electronic device case 102.

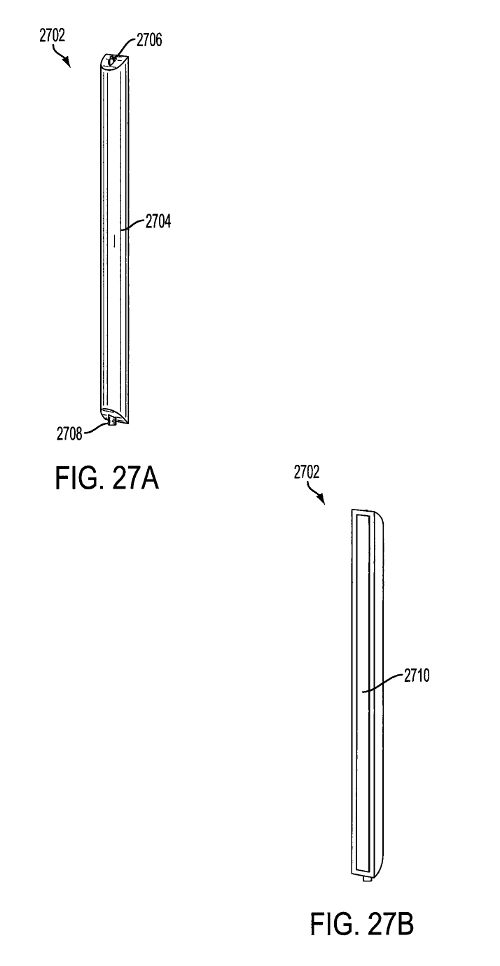

FIG. 27 illustrates an embodiment where the accessory is a writing tool 2702. The writing tool 2702 includes a body 2704, a marking tip 2706, and an attachment mechanism 2710. The marking tip 2706 can be any writing tip or nib that is used for writing or marking, including, but not limited to, a pencil lead or graphite, ball point pen, felt tipped pen, fountain pen, gel pen, roller ball pen, marker, and/or highlighter. Any other writing implement can be equally used in the present embodiments. In some embodiments, the writing tool 2702 includes a retraction button 2708 for actuating a retraction mechanism that draws the marking tip 2706 into the body 2704 of the writing tool. This can help prevent the writing tool 2702 from making inadvertent markings when the writing tool 2702 is attached to the mobile electronic device case.

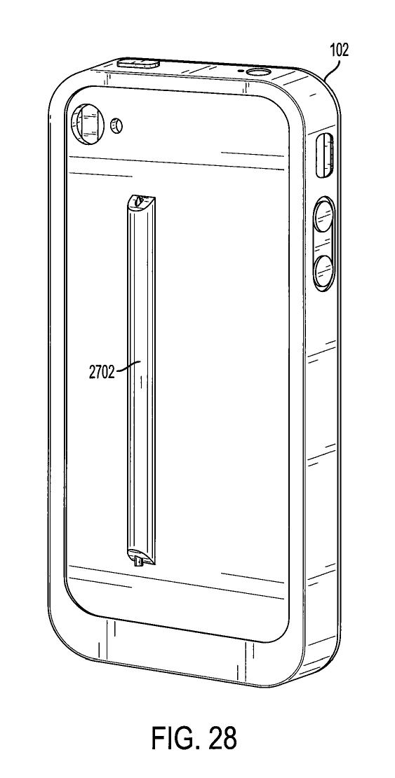

FIG. 28 illustrates an embodiment of the writing tool 2702 removably attached to a mobile electronic device case 102.

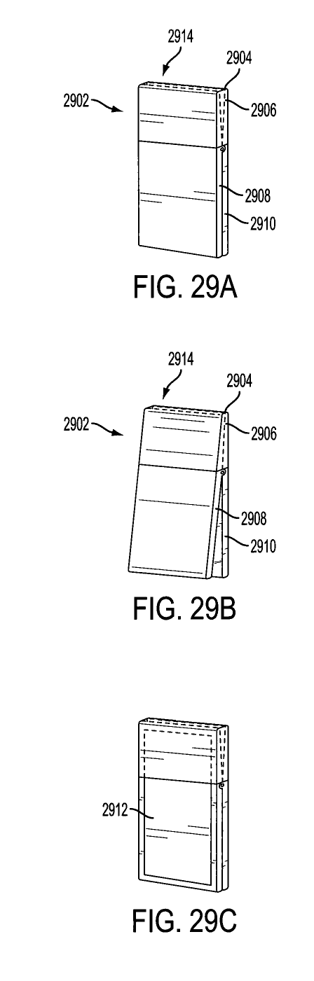

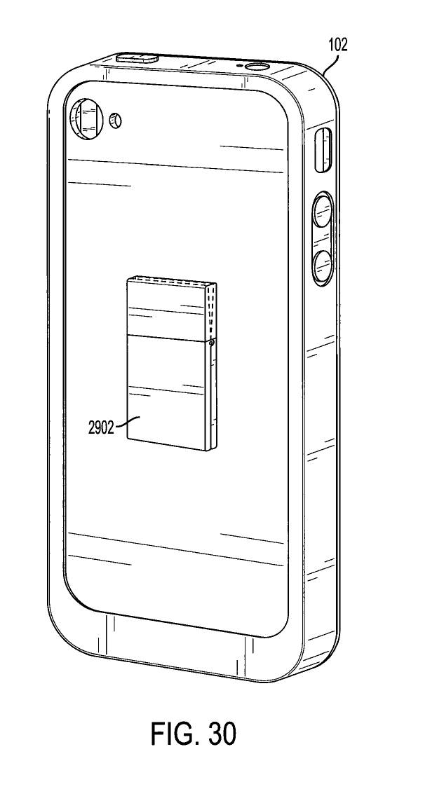

FIGS. 29 and 30 illustrate an embodiment where the accessory is a spring clip 2902 (sometimes referred to as “clip 2902”), with an attachment mechanism 2912. In some embodiments, the spring clip 2902 includes a first opening tab 2904 and a second opening tab 2906. The spring clip 2902 also includes a first gripping tab 2908 and a second gripping tab 2910. Opening tabs 2904, 2906 are portions of the clip that a user can squeeze together in order to open the gripping tabs 2908, 2910. The gripping tabs 2908, 2910 and the opening tabs 2904, 2906 are connected with a spring that biases the first and second gripping tabs 2908, 2910 in a closed position. This allows the spring clip 2902 to advantageously hold any items securely between the gripping tabs 2908, 2910. When the gripping tabs 2908, 2910 are in the closed position, the gripping tabs 2908, 2910 are nearer to one another than the opening tabs 2904, 2906. Additional gripping tabs or opening tabs may also be used without departing from the spirit of the invention. For example, in some embodiments, the clip 2902 contains three, four, or more gripping tabs. FIG. 29B illustrates the clip 2902 in an open position

In some embodiments, the opening tab 2904 and the gripping tab 2908 (or tabs 2906 and 2910) are formed from the same piece of material, such as metal, plastic, polymer, fiberglass, wood, and/or rubber. In some embodiments, they are individual components, but are connected to each other either directly or indirectly. In some embodiments, the spring clip 2902 is thinner than the thickness of the mobile electronic device case 102.

The particular type, location, and orientation of the spring can vary depending on the particular design of the spring clip 2902. For instance, in some embodiments the spring can be located between the first and second opening tabs 2904, 2906, or between the first and second gripping tabs 2908, 2910. In some embodiments, the spring can be an integral part of a hinge that connects the gripping tabs 2908, 2910. One of skill in the art will recognize various methods of using springs or other materials in order to bias the first and second gripping tabs 2908, 2910 in a closed, securing position.

In some embodiments, when a spring clip 2902 is in a closed position, the opening tabs of the clip may have exposed edges that can be inconvenient for a user of the accessory system. For instance, the exposed edges could catch on the inside of a pocket or purse, inhibiting the easy extraction of the mobile electronic device case when the spring clip accessory is in use, or causing the spring clip accessory to be unintentionally removed from the case. Thus, in some embodiments, the spring clip 2902 includes a cover 2914 over a portion of the spring clip 2902, covering the exposed edges of the opening tabs 2904, 2906 so that they will be less likely to snag or catch on other surfaces or materials. In some embodiments, the cover 2914 is a piece or assembly of flexible material that is attached to the opening tabs 2904, 2906, and will deform when a user applies pressure to one or both of the opening tabs 2904, 2906 in order to open the gripping tabs 2908, 2910 of the clip 2902. In some embodiments, the cover material is rubber, elastomer, plastic, fabric, leather, or any other material that will provide the functionality described above.

FIG. 30 illustrates an embodiment of the spring clip 2902 removably attached to a mobile electronic device case 102.

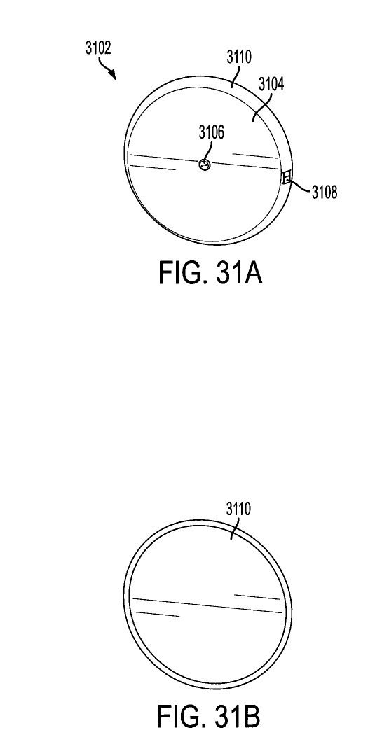

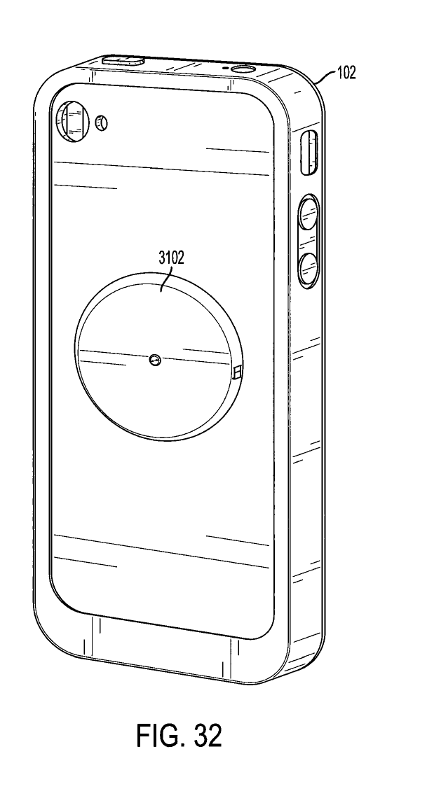

FIGS. 31 and 32 illustrate an embodiment where the accessory is a tape measure 3102. In some embodiments, the tape measure 3102 includes a housing 3104, a tape with graduated markings for measuring length, a tape-lock release button 3106, and a tape handle 3108. The tape measure 3102 also has an attachment mechanism 3110. The tape can be configured to be contained within the housing 3104 when the accessory is not in use. In some embodiments, the tape measure 3102 has a ratchet mechanism within the housing, such that when the tape is drawn out from within the housing, the ratchet mechanism locks the tape in an extended position. Furthermore, the ratchet mechanism can employ a spring-return mechanism, such that when the tape-lock release button 3106 is depressed by a user, the tape is drawn back into the housing 3104 for storage. In some embodiments, the tape-lock release button is flush with the housing 3104 when the button is in an un-depressed state. In some embodiments, the tape measure 3102 includes a crank handle in conjunction with a tape-retrieval mechanism for re-spooling the tape measure into the housing 3104.

In some embodiments, the housing 3104 of the tape measure 3102 is substantially equal to or less than 1 inch thick. In some embodiments, the tape measure 3102 is substantially equal to or less than 0.5 inches thick. In some embodiments, the tape measure 3102 is substantially equal to or less than 0.25 inches thick. In some embodiments, the tape measure 3102 is thinner than the recess in the case 102, as described in greater detail above with reference to FIG. 1. In some embodiments, the housing 3104 of the tape measure 3102 has a beveled edge 3110.

In some embodiments, the components of the tape measure 3102 are made of any suitable material or combination of materials, including, but not limited to, plastic, elastomer, silicone, wood, metal, fiberglass, polymer, and/or rubber. The specific material or materials used may depend on the particular design chosen for the components of the tape measure 3102, and such design choices can be made without departing from the spirit of the invention.

FIG. 32 illustrates an embodiment of the tape measure 3102 removably attached to a mobile electronic device case 102.

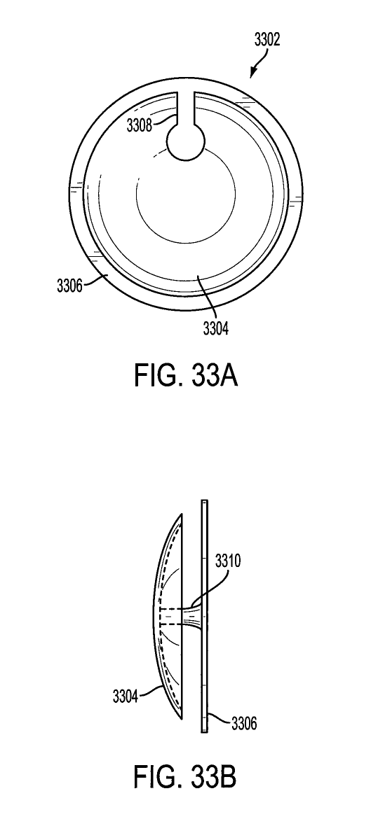

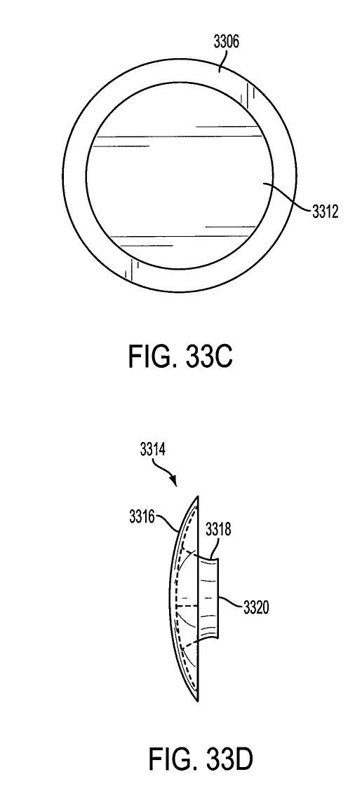

FIG. 33 illustrates an embodiment where the accessory is a cable winder 3302 (“winder” 3302). The winder 3302 includes a front retaining member 3304 and a mounting member 3306. The mounting member 3306 has an attachment mechanism 3312 for removably attaching the winder 3302 to a surface of a mobile electronic device case.

In some embodiments, the front retaining member 3304 and the mounting surface 3306 are connected by a wrapping shaft 3310. A user can wind a cable, such as a headphone cable, microphone cable, charging cable, etc., around the wrapping shaft 3310, so that the wrapped cable is positioned between the front retaining member 3304 and the mounting member 3306. Thus, a cable can be conveniently stored on the winder 3302 for later retrieval. In some embodiments, the winder 3302 also includes a cable retaining mechanism for holding at least one end of a cable, such as the ear-bud end of a set of headphones. In some embodiments, the cable retaining mechanism is a slot 3308 in the front retaining member 3304. In some embodiments, the wrapping shaft 3310 is removably coupled to the mounting member 3306 and/or the front retaining member 3304 such that a portion of the winder 3302 can be de-coupled to allow easier access to a cable that is stored on the winder 3302.

FIG. 33D illustrates an alternative embodiment of a winder 3314, where the winder 3314 has a front retaining member 3316, a wrapping shaft 3318, and a mounting surface 3320 with a diameter that is not substantially larger than the diameter of the wrapping shaft 3318. In this case, when a cable is wrapped around the wrapping shaft 3318, the cable is not held “between” the mounting surface 3320 and the front retaining member 3316, because the mounting surface 3320 is not large enough. Rather, a user can wrap a cable around the wrapping shaft 3318 when the winder 3314 is attached to a surface of a mobile electronic device case. In this case, the surface of the mobile electronic device case will act as a second holding surface to keep the wrapped cable captive between the front retaining member 3316 and the surface of the case. Furthermore, in this embodiment, when a user wishes to retrieve and use the cable, the winder 3314 can simply be detached from the surface of the case, and the cable will readily uncoil or unwrap from the wrapping shaft 3318.

While the above winders 3302, 3314 are described as having circular dimensions, one of skill in the art will recognize that other shapes can be equally used without departing from the spirit of the invention.

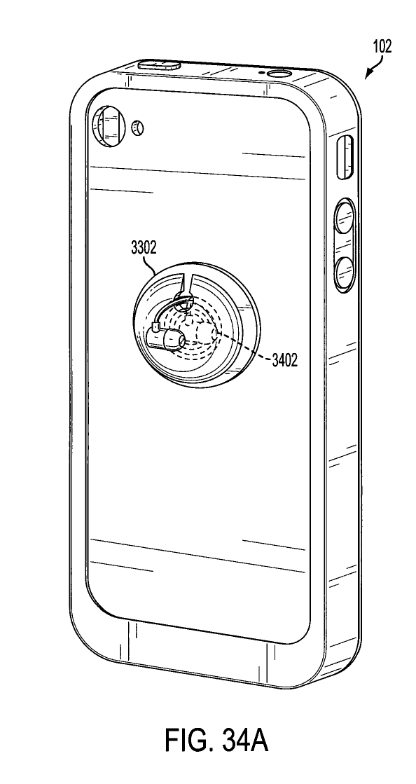

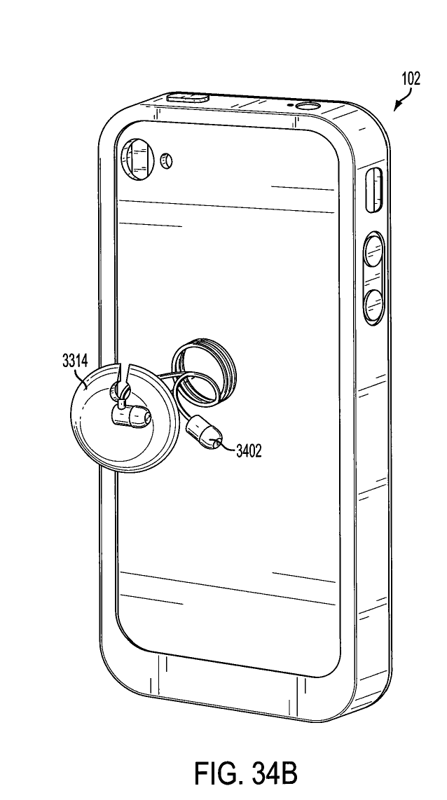

FIG. 34A illustrates an embodiment of the winder 3302 attached to a surface of the mobile electronic case 102, with a headphone cord 3402 wrapped around it. FIG. 34B illustrates an embodiment of the winder 3314 in conjunction with a mobile electronic device case 102, illustrating how a user can remove the winder 3314 from the case to easily uncoil a set of headphones 3402.

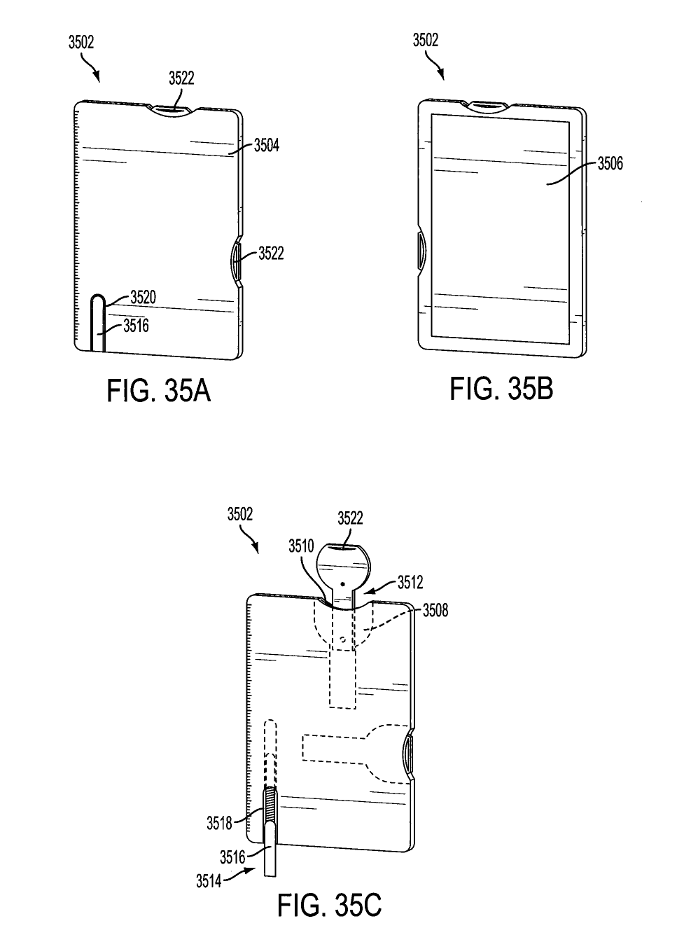

FIG. 35 illustrates an embodiment where the accessory is a flat multiple tool holder accessory 3502 (sometimes referred to also as “tool holder 3502”). The tool holder 3502 includes a housing 3504, where the housing is configured to fit substantially within the area defined by the surface 104 of the mobile electronic device case 102. The tool holder 3502 also includes an attachment mechanism 3506 connected with the housing for removably attaching the housing 3504 to the surface 104 of the mobile electronic device case 102.

The housing 3504 of the tool holder 3502 defines at least one internal chamber 3508, and has at least one opening 3510 opening into the internal chamber 3508. The chamber and the opening are configured to enclose at least a portion of an instrument 3512 for secure storage.

In some embodiments, an instrument 3512, 3514 can be any tool or implement that can be configured to fit within the housing 3504. For instance, the instrument could be any one of the following types of tools: screwdrivers; tweezers; toothpicks; scissors; pliers; a key; knifes; blades; reamers; pins; Allen wrenches; torx wrenches; files; saws; magnifying glasses; rulers; flashlights; corkscrews; pins; needles; bottle openers; wire cutters; wire strippers; chisels; can openers; and computer memory devices. Other, specialized instruments could be included as well, including divot repairers; golf ball markers; marlin-spikes; fish scalers; hook disgorgers; and cigar cutters.

In some embodiments, an instrument 3514 includes a handle portion 3516 such that the handle portion 3516 substantially fills in an opening 3518 in the housing 3504. The handle portion 3516 can be configured to be a particular size and shape so that, when the instrument 3514 is situated in the storage position (e.g., when the instrument is at least partially contained within an internal chamber), the handle portion 3516 substantially fills the opening 3518 in the surface of the housing 3504. Furthermore, in some embodiments, when the instrument 3514 is in the storage position, the handle portion 3516 can be dimensioned such that it does not protrude substantially from the outer surface of the housing 3504. In this configuration, when all the tools are in their storage positions, the housing 3504 and the handles 3516 form a substantially continuous surface. (For example, handle 3516 and housing 3504 are shown in FIG. 35A as forming a substantially continuous surface.) In some embodiments, the interfacing portions of the handle portion 3516 and the housing 3504 will not form a perfectly continuous surface, but rather will form a small gap or channel 3520 between them. This gap or channel 3520 can be advantageously employed by a user as a gripping mechanism, whereby the user can more easily extract the instrument 3514 from the opening of the housing 3504 with a fingernail or finger tip, for example. In some embodiments, the handles of the instruments include a grip 3522 for aiding in the removal of a tool from the housing 3504.

One of skill in the art will recognize that the particular selection of types of instruments and the location of the openings may change based on different considerations. For example, it may be beneficial to locate the instruments and openings to make the most efficient use of the space within the housing so that the maximum number of instruments can be included in the accessory.

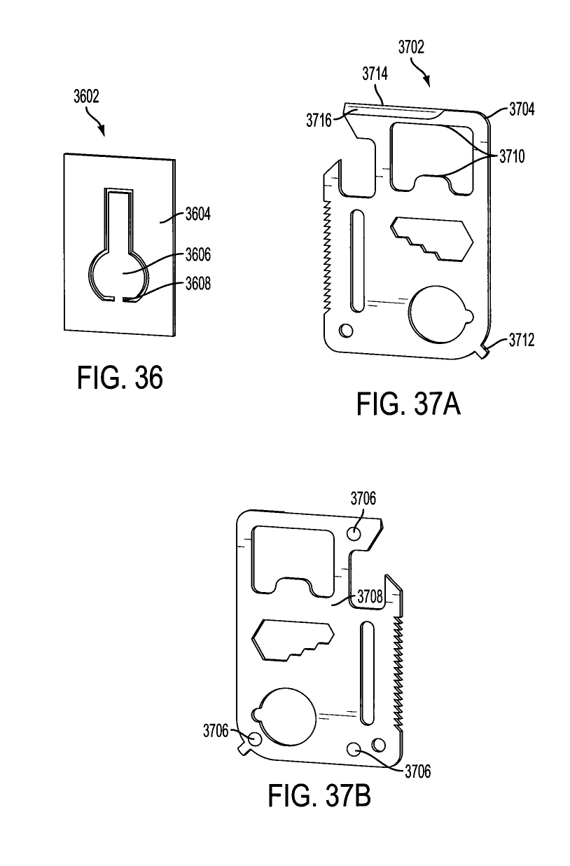

FIG. 36 illustrates an embodiment where the accessory is a card with a fold-out key, or a key-card 3602. The key-card 3602 includes a body 3604, a key 3606, and a flexible connection element 3608 for joining the body 3604 to the key 3606. One side of the key-card 3602 will also include an attachment mechanism in accordance with those described above with relation to FIG. 1. For instance, in some embodiments, the key-card 3602 has a magnet or magnet material to allow the key-card to removably attach to a mobile electronic device case with a magnetic material and/or metal back. Furthermore, in some embodiments, the body 3604 of the key-card is sized to fit substantially within the area defined by the surface of the mobile electronic device case.

The key-card herein described can be used as an emergency or replacement key. The key can be configured and cut for any type of lock or device. For instance, the key could be a replacement house key, garage key, automobile key, motorcycle key, or any other kind of key. In some embodiments, the flexible connection element 3608 allows a user to fold the key 3606 perpendicular to the body 3604 so that the key can be inserted into the door, lock, ignition, etc. In some embodiments, the flexible connection element 3608 is a piece of deformable plastic. In some embodiments, the entire key-card 3602 is manufactured from a single piece of material, such as plastic, metal, or the like. In some embodiments, the flexible connection element 3608 is a hinge. While the key-card 3602 can be used as an emergency or replacement key, it can also be manufactured from a material that exhibits sufficient strength (so that the key can be used frequently, or as a main key, for a specific lock. Furthermore, when a hinge mechanism is used rather than a flexible portion of plastic, for example, the key 3606 can be folded perpendicular to the body 3604 many times. By contrast, many plastics or polymers would only allow the key 3606 to be folded a relatively few number of times before the key 3606 will snap off from the body 3604. In some embodiments, the key 3606 is designed to snap off from the body 3604 after only a single use, or a few uses. One of skill in the art will recognize that various different materials for the body 3604, key 3606, and flexible connection element 3608 can be advantageously used to achieve a variety of design goals, particularly with respect to the intended durability of the key-card 3602.

FIGS. 37-40 illustrate an embodiment where the accessory is a flat multi-tool 3702 (referred to herein as “multi-tool 3702”). The multi-tool 3702 includes a plurality of individual tools in combination. The multi-tool 3702 has a peripheral outer edge 3704 that is configured to fit substantially within an area defined by a surface of a mobile electronic device case. The multi-tool 3702 further includes at least one attachment mechanism 3706 attached to a surface 3708 of the multi-tool. The attachment mechanism 3706 allows the multi-tool to be removably attached to a surface of a mobile electronic device case. In some embodiments, the attachment mechanism is on a back side of the multi-tool. In some embodiments, the multi-tool 3702 is made from a single piece of material, such as polymer, metal, magnets, or magnetic material. Other variations on the attachment mechanism 3706 and the mechanisms by which the multi-tool can be removably connected to the case 102 are described in more detail with reference to FIG. 1. Though the multi-tool can be any thickness, in some embodiments it is made as thin as possible to reduce its weight and footprint so that it can be more convenient to mount and store the multi-tool on a surface of a mobile electronic device case. In some embodiments, the multi-tool is of sufficient thickness to provide each tool with the strength needed for it to perform its intended function. In some embodiments, the multi-tool is 1/32 inch, 3/64 inch, or 1/16 inch. The particular thickness of the multi-tool will depend in part on the strength required and the particular material chosen for the multi-tool.

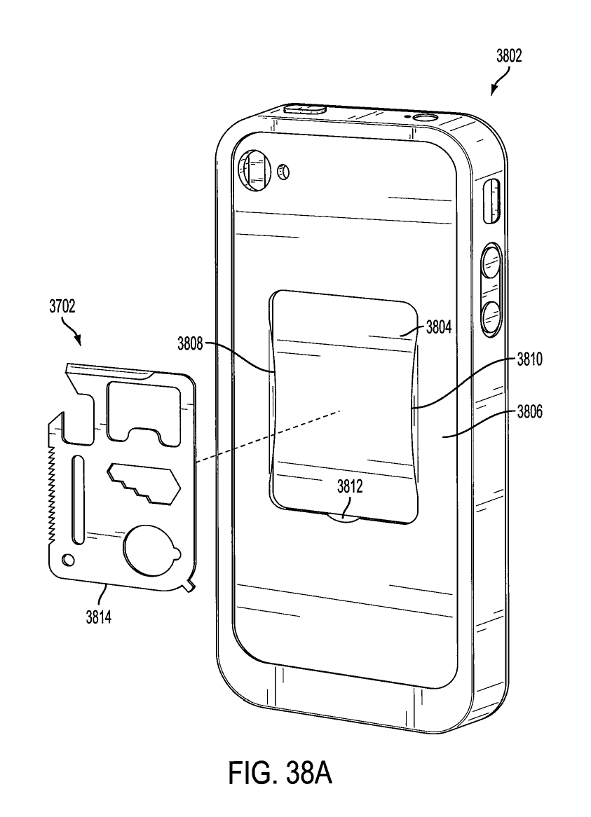

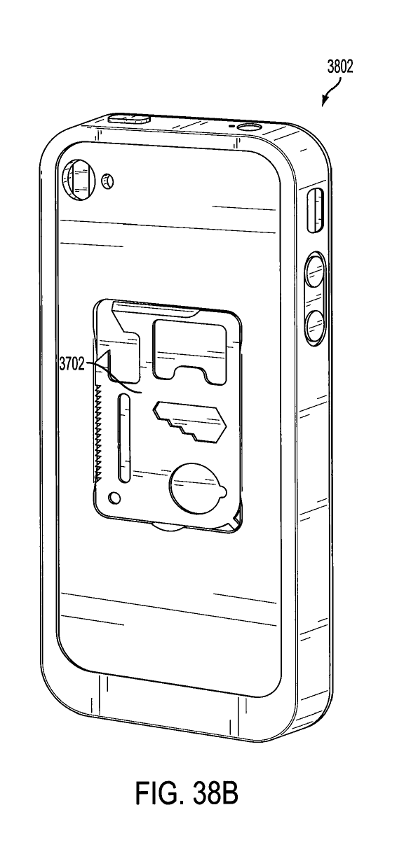

FIG. 38 illustrates a mobile electronic device case 3802 for use in conjunction with a flat multi-tool where the device case is configured with a recess specifically for holding the flat multi-tool in a storage position. As shown, the mobile electronic device case 3802 has a recess 3804 on the back of the case 3802 that is configured to receive the multi-tool 3702 therein. The recess is configured to be substantially the same size and shape as the periphery of the multi-tool. In some embodiments, the recess has a depth equal to or greater than the thickness of the multi-tool, so that the exposed surface of the multi-tool 3702 does not extend beyond the surface 3806 of the back of the case 3802.

In some embodiments, an attachment mechanism is used to keep the multi-tool 3702 securely mounted in the recess 3804 when the multi-tool is stored. As described above with reference to FIG. 1, various attachment mechanisms can be used, including magnets, magnetic materials, Velcro, and the like. In some embodiments, the case utilizes a semi-flexible material for the walls 3808 of the recess 3804 to act as a retaining mechanism to keep the multi-tool 3702 held securely within the recess. In some embodiments, the entire back of the case, or only discrete portions of the walls of the recess, is made of a semi-flexible material.

The recess is configured to have at least one dimension that is smaller than the corresponding dimension of the multi-tool 3702. In other words, the length or width of the recess is slightly smaller than the periphery of the multi-tool in at least one location, so that the walls of the recess will “grip” the edges of the multi-tool 3702 at that location. In some embodiments, the walls of the recess have at least one protrusion 3810 that contacts peripheral edge of the multi-tool. When the multi-tool is to be stored, it is inserted into the recess and the edges of the multi-tool 3702 will slightly deform protrusion 3810, causing a pressure between the protrusion (or the walls of the recess), and the edge of the multi-tool, so that the multi-tool 3702 is held securely in the recess 3704. It should be noted that the precise amount of force created between the case 3802 and the multi-tool 3702 will depend on the size of the protrusion 3810 and the relative flexibility of the material chosen for the walls of the recess 3804. While there is no single preferred amount of force between the case and the multi-tool, the sizes and materials selected for the components of the system should be such that the multi-tool is held securely in the recess 3804 during normal use of a mobile electronic device. In other words, the multi-tool should be held securely enough that the multi-tool does not come out of the recess at unintended times. However, the force should be sufficiently low that a user can easily remove the multi-tool 3702 from the recess when the multi-tool is to be used.

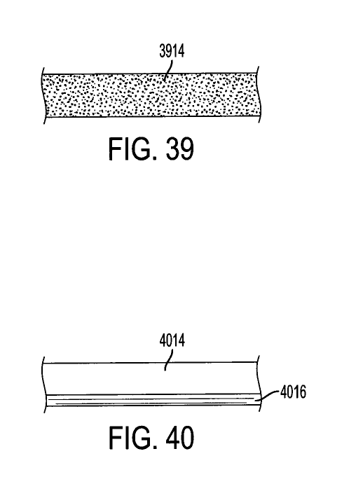

In some embodiments, one wall of the recess has a cut-away portion 3812 so that a user can more easily grip the edge of the multi-tool 3702 for removal from the recess 3804. In some embodiments, the location of the cut-away portion 3812 corresponds to a location on the multi-tool that includes a gripping element 3814. In some embodiments, as shown in FIG. 39, the gripping element 3814 is a textured surface on the edge of the multi-tool. In some embodiments, as shown in FIG. 40, the gripping element 3814 is a portion of the edge of the multi-tool that is not flush with the inner surface of the recess. In other words, there is a gap 3816 between the surface of the case 3802 and the multi-tool 3702 such that a user could use a fingernail or portion of a finger tip to grip and remove the multi-tool.

It should be noted that the recess 3804 of the case does not necessarily have to include the retaining mechanism as described above with reference to FIG. 38. The case can include additional or alternative attachment systems as well. For instance, in some embodiments, the multi-tool 3702 can be held in the recess 3804 by the attachment mechanisms described above with reference to FIG. 1. For example, in some embodiments, the multi-tool 3702 and the case 3802 include a magnetic attachment mechanism as described above with reference to FIG. 1. Thus, when the multi-tool 3702 is inserted into the recess 3804 of the case, the multi-tool is held in place by the magnetic attachment mechanisms. In some embodiments, the magnetic attachment mechanism is used in conjunction with or instead of the protrusion retaining mechanism described above with reference to FIG. 38.

FIG. 38B illustrates an embodiment of the flat multi-tool accessory 3702 removably attached in a recess of a mobile electronic device case 3802.

Attention is now turned to exemplary embodiments of the multi-tool, illustrated in FIG. 37. In some embodiments, the individual tools of the multi-tool 3702 are formed by the particular location, size, and configuration of recesses and edges in the material of the multi-tool 3702. For instance, in some embodiments, the multi-tool includes a bottle opener tool 3710, which is formed by a substantially rectangular hole in the multi-tool. In some embodiments, the multi-tool includes a screwdriver blade 3712, which is an edge of the multi-tool 3702 that has the shape of a rectangular tab for insertion into the slot of a slotted or Phillips head screw. In some embodiments, the multi-tool includes one or more internal openings that are stencils of various shapes.

Also, in some embodiments, the multi-tool 3702 includes a blade 3714 that is a sharpened portion of an outer edge of the multi-tool 3702. The blade 3714 can be configured so that the sharp edge is formed by a single bevel 3716 on a top side of the multi tool. In this way, the sharp edge of the blade 3714 will have one side that is flush against the surface of the mobile electronic device case 102 (or 3802), to prevent the sharp edge from inflicting unintended injuries when the case and the multi-tool are being transported and stored. Specifically, the case 102 (or 3802) with the multi-tool 3702 attached could safely be inserted into and removed from a user's pocket without fear that the blade will cut the user's pocket or their skin. In some embodiments, other tools can be included in the multi tool, including but not limited to: a ruler; a can opener; a bottle opener; a blade; a screwdriver; a saw; a pry-tool; a knife; and a wrench.

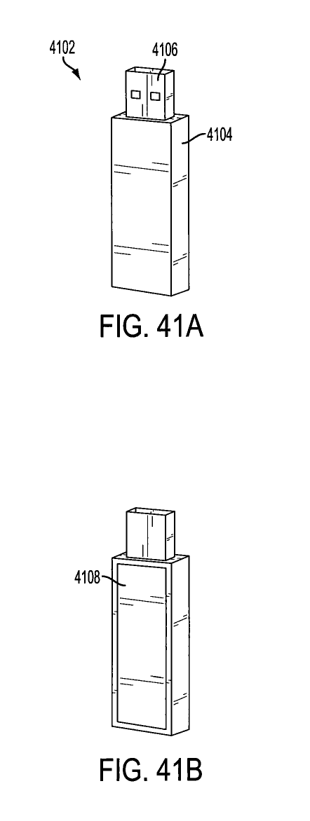

FIGS. 41-45 illustrate embodiments where the accessory is a digital storage device 4102 for connection to a mobile electronic device case. In some embodiments, the digital storage device includes a body 4104 configured to fit substantially within an area defined by the surface of a mobile electronic device case. The storage device 4102 also includes a re-programmable, non-volatile flash memory element. Such flash memory devices are known in the computer arts, and are not described at length here. It should be noted that any re-programmable, non-volatile memory now known or later developed can be employed in the digital storage device 4102. Furthermore, a “digital storage” device is to be understood as any memory device capable of digitally storing information. Thus, a “computer memory device” need not connect only to a personal computer, but also any electronic device using memory, such as a digital camera, digital camcorder, PDA, video game console, etc. The digital storage device 4102 also includes an interface connector 4106 for connecting the storage device 4102 with a computer. The digital storage device 4102 also includes at attachment mechanism 4108 connected with the body 4104 for removably attaching the digital storage device 4102 to the surface of the mobile electronic device case 102.

In some embodiments, the interface connector is any composition of materials that allows the digital storage device 4102 to form a data communication with a computer. In some embodiments, the interface connector includes a physical connector in accordance with an industry standard connector design, such as a Universal Serial Bus (USB) connector. In some embodiments, the interface connector is any component or set of components for bringing the digital storage device 4102 into data communication with a computer or other electronic device. For example, in some embodiments, the computer interface connector is a USB connector without an outer connector frame. In some embodiments, the interface connector is the contacts on an SD card, or any other type of flash memory card.

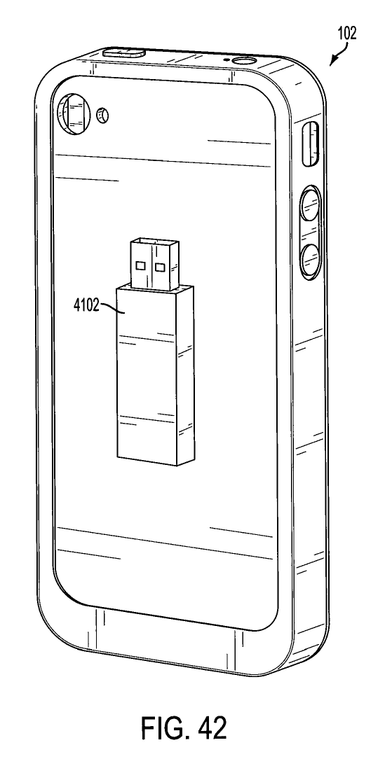

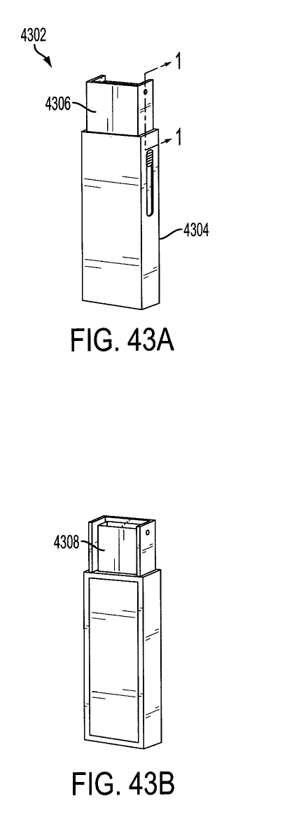

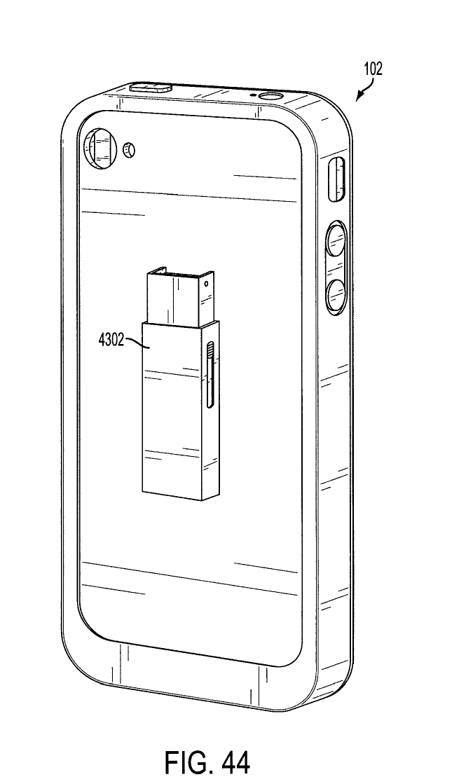

As shown in FIGS. 41-42, some embodiments of the digital storage device 4102 do not have any cover over the interface connector 4106. As shown in FIGS. 43 and 44, however, some embodiments of a digital storage device 4302 have a cover 4306 that is slidably attached with the body 4304. The cover 4306 has a first open position and a second closed position. When the cover 4306 is in the first open position, the interface connector 4308 is exposed to allow the interface connector 4308 to be connected with a computer.

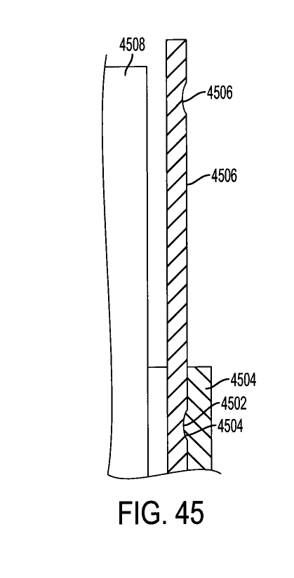

In some embodiments, the cover 4306 includes a retaining mechanism such that when the cover 4306 is in the second closed position, the cover 4306 is preferentially maintained in the second closed position (as shown in FIG. 43). FIG. 45 is a sectional view of the digital storage device 4302 illustrating the retaining mechanism. In some embodiments, the retaining mechanism is a detent mechanism with a protrusion 4502 and at least one recess 4504, 4506. When the cover 4306 is in the second closed position, the protrusion 4502 is received in the recess 4504, and prevents the cover from being inadvertently opened into the first open position when the digital storage device 4302 is being stored or manipulated when connected to a portable electronic device case. In some embodiments, when the cover 4306 is in the first open position, the protrusion 4502 is received in a second recess 4506, and prevents the cover 4306 from being closed.

One of skill in the art will recognize that the connection with the computer described herein need not be a direct physical connection to a computer, but rather describes a functional data communication connection between the digital storage device and a computer. For example, the digital storage device could be connected with a USB hub that is, in turn, connected with a computer, either via electrical conductors or wirelessly.

FIGS. 42 and 44 illustrate digital storage devices 4102, 4302, respectively, removably attached to a surface of a mobile electronic device case 102.

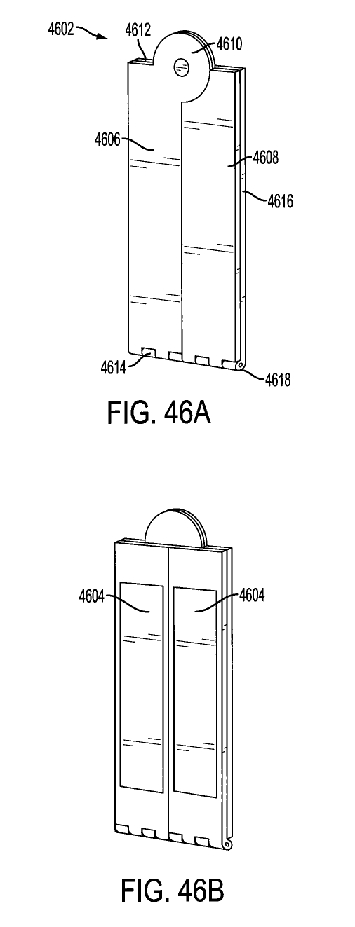

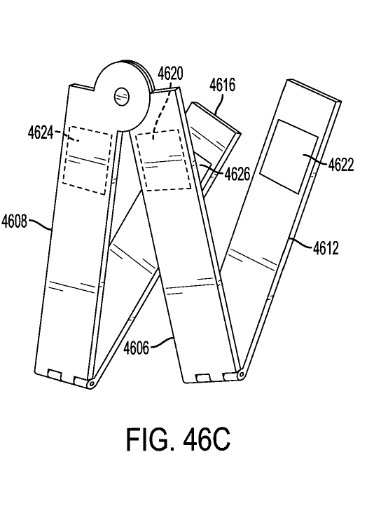

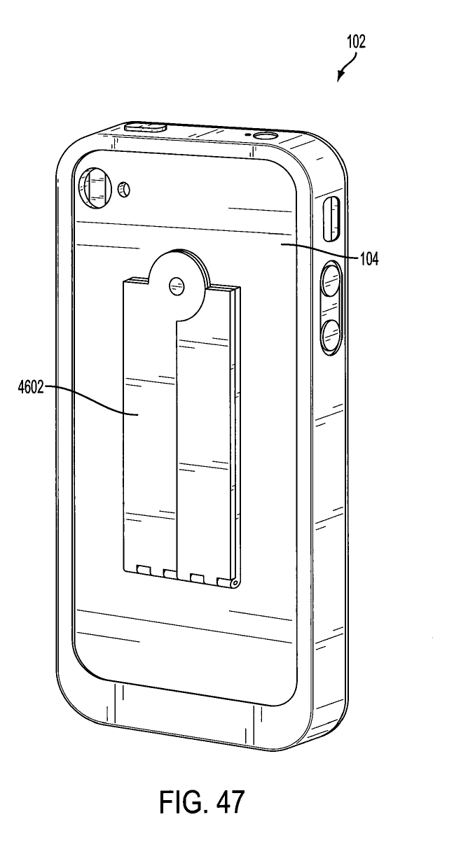

FIGS. 46 and 47 illustrate an embodiment where the accessory is a ruler 4602. As shown in FIG. 47, the ruler 4602 is configured to fit substantially within an area defined by a surface 104 of the mobile electronic device case 102. FIG. 46B shows the ruler with an attachment mechanism 4604 attached with the ruler 4602 for removably attaching the ruler to the surface 104 of the mobile electronic device case 102.

In some embodiments, the ruler includes a first segment 4606 and a second segment 4608, and at least one joint 4610 connecting the segments 4606, 4608 such that the ruler 4602 has at least a first position and a second position. When the ruler 4602 is in the first position, the ruler is at least partially collapsed, and fits completely within an area defined by the surface 104 of the mobile electronic device case 102. By allowing the ruler 4602 to collapse, it is possible for the ruler to have a longer measuring edge than a fixed length ruler that is configured to fit inside the same area of the mobile electronic device case. In some embodiments, the ruler 4602 has a third segment 4612 connected with the first segment 4606 by a second joint 4614, and a fourth segment 4616 connected with the second segment 4608 with a third joint 4618. In some embodiments, the third and fourth segments 4612, 4616 are substantially the same length as the first and second segments 4606, 4608. The second and third joints 4618, 4618 allow the third and fourth segments 4612, 4616 to collapse in order to allow convenient storage of the ruler 4602 against the surface 104 of the mobile electronic device case 102. As shown in FIG. 46C, in some embodiments, the first segment 4606 includes a first segment attachment mechanism 4620, and the third segment 4612 includes a second segment attachment mechanism 4622. The first and second segment attachment mechanisms 4620, 4622 provide an attractive force between the first and third members 4606, 4612 when the ruler is in the first, partially collapsed, position. This helps to prevent the ruler 4602 from being accidentally unfolded. In some embodiments, the second and fourth segments 4608, 4616 have similar segment attachment mechanisms 4624, 4626.

In some embodiments, the attachment mechanism 4604 and the segment attachment mechanisms 4620, 4622, 4624, and 4626 are either magnets or magnetic materials. Thus, the accessory can be attached to a metal back of a case for a mobile electronic device by means of a magnetic attraction between the magnets/magnetic materials and the metal back. However, many alternative attachment mechanisms can be used without departing from the spirit of the invention. More detailed descriptions of alternative attachment mechanisms can be found above with reference to FIG. 1.

In some embodiments, the components of the ruler 4602 are made of any suitable material or combination of materials, including, but not limited to, plastic, elastomer, silicone, wood, metal, fiberglass, polymer, and/or rubber. The specific material or materials used may depend on the particular design chosen for the components of the ruler 4602, and such design choices can be made without departing from the spirit of the invention.

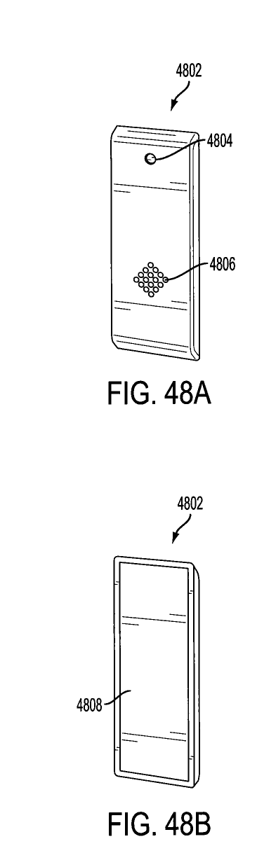

FIG. 48 illustrates an embodiment where the accessory is an audible alarm 4802. The audible alarm includes a body 4810, a control button 4804 and a speaker 4806. On at least one side, the audible alarm 4802 includes a magnetic attachment element 4808 for removably attaching the audible alarm 4802 to the surface of a mobile electronic device case.

In some embodiments, the audible alarm 4802 contains electronics and a power source (e.g., a battery) so that when the control button 4804 is depressed by a user, the audible alarm 4802 emits a very loud sound from the speaker 4806. In some embodiments, the sound is above 110 dB. In some embodiments, the sound is above 120 dB. In some embodiments, the sound is above 130 dB. Thus, the audible alarm 4802 can be used as a personal safety device. A user can use the loud sound from the alarm to alert nearby people if the user is in trouble in any way.

In some embodiments, the audible alarm 4802 contains electronics and a power source, where the electronics contain a receiver and/or transmitter. In some embodiments, the electronics in the audible alarm 4802 are capable of receiving a signal from a remote device that will cause the speaker 4806 to emit a sound. A user can removably attach the audible device to a surface of a mobile electronic device case. A user can then remotely activate the audible alarm 4802, whereupon the user will be able to hear the alarm to help find a lost or misplaced phone. In some embodiments, the system includes a remote control for attachment to a keychain, where the remote control can activate the audible alarm 4802 from a certain physical distance. In some embodiments, the remote control is also an audible alarm, so that the remote control and the audible alarm could each be used to activate the speaker on the other device in order to assist a user in locating the lost or misplaced item. Furthermore, in some embodiments, the “locating” functionality can be combined with the “personal safety alarm” functionality in the same audible alarm 4802.

One of skill in the art will recognize additional configurations and combinations of remote controls and audible alarms that can be employed in the present invention. Furthermore, the specific electronic components and mechanisms for creating a sound from a speaker, receiving a signal from a remote control, and transmitting a signal from a remote control are not described in detail here. One of skill in the art will understand that a variety of mechanisms, technologies, and materials can be used in the audible alarm accessory without departing from the spirit of the invention.

FIG. 49 illustrates the audible alarm 4802 removably attached to a surface of a mobile electronic device case 102.

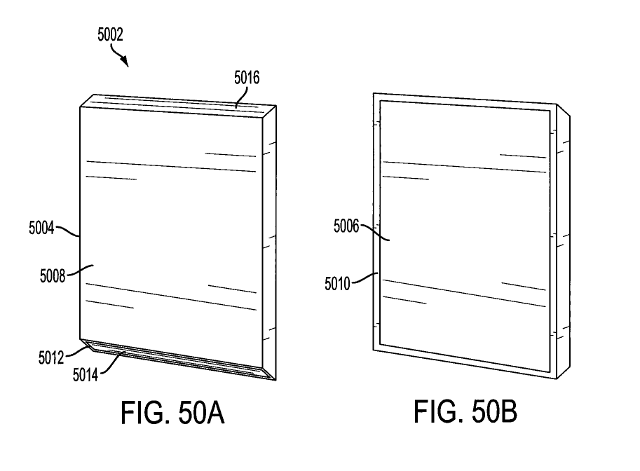

FIGS. 50-56 illustrate embodiments where the accessory is a support accessory 5002. Support accessories as shown and described may be used to prop up or support a mobile electronic device in a viewing or “display” position. As described more fully below, the support accessories can be configured to have a stored position and a supporting position, such that the support accessory 5002 can be employed to prop up a mobile electronic device when desired, and stored conveniently on the mobile electronic device (or a case for a mobile electronic device) when not in use. When the case 102 is supported by the support accessories described below, a user can easily view a screen of the mobile electronic device without needing to hold the device, or prop the device using some other, less secure means.

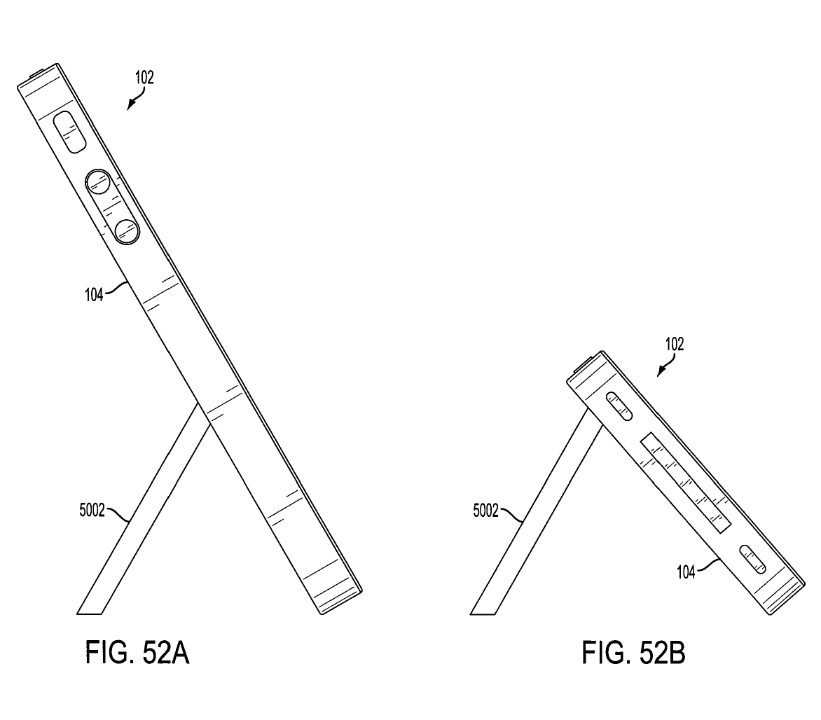

FIG. 50 illustrates an embodiment of the support accessory 5002. In some embodiments, the support accessory includes a support member 5004 and a magnetic attachment element 5006 attached with the support member for removably attaching the support accessory 5002 in a supporting position to a surface 104 of a mobile electronic device case 102. As shown in FIG. 52, when the support accessory 5002 is attached to the surface 104 of the case 102 in the supporting position, the support member 5004 maintains the mobile electronic device case 102 in a semi-upright position.

Returning to FIG. 50, in some embodiments, the support accessory 5002 includes a first side 5008, a second side 5010 that is substantially parallel to the first side 5008, and a third side 5012 with at least one magnet 5014. The third side forms a beveled surface between the first and second sides 5008 and 5010 such that when the third side 5012 is attached with the surface 104 of the mobile electronic device case 102, the supporting member 5004 is magnetically held in the supporting position.

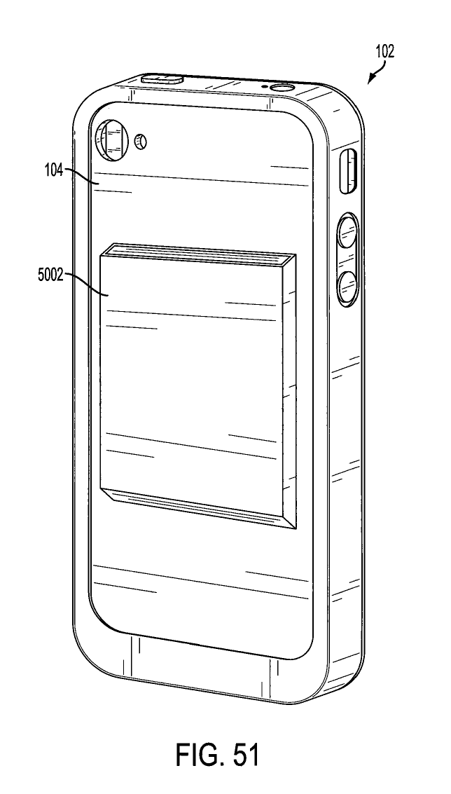

In some embodiments, one of the first or second sides 5008, 5010 of the support accessory 5002 includes a magnet as the magnetic attachment element 5006 for mounting the support member in a stored position on the surface 104 of the mobile electronic device case 102. In some embodiments, the magnet is attached to the longer side 5010 of the support member 5004, so that the beveled edges 5012, 5016 form an obtuse angle with the exposed surface 104 of the case 102. FIG. 51 illustrates the support accessory 5002 attached to a surface 104 of a mobile electronic device case 102 in accordance with some embodiments.

FIG. 52A illustrates the support accessory 5002 supporting the mobile electronic device 102 case in a “portrait” orientation. FIG. 52B illustrates the support accessory 5002 supporting the mobile electronic device case 102 in a “landscape” orientation.

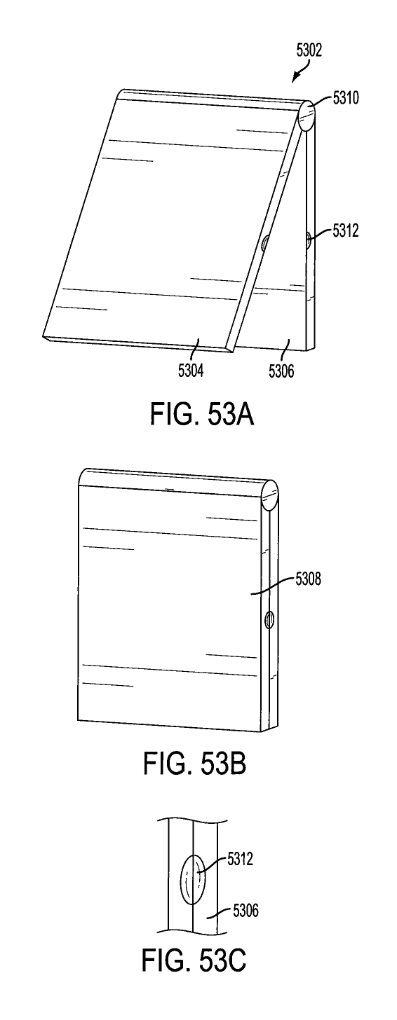

As shown in FIG. 53, in some embodiments, a support accessory 5302 includes a support member 5304, and a mounting member 5306 hingably attached with the support member 5304. The support member 5304 can be moved between a first collapsed position (shown in FIG. 53A), and a second operating position (shown in FIG. 53B). In some embodiments, the mounting member 5306 includes an attachment mechanism 5308 for removably attaching the support accessory 5302 in a supporting position to a surface 104 of a mobile electronic device case 102.

In some embodiments, the support member 5304 and the mounting member 5306 are connected with each other by a hinge mechanism 5310. The hinge mechanism can be any type of hinge or other mechanism, material, or any combination of hinges, mechanisms, and materials, that allows the support member 5304 and the mounting member 5306 to rotate with respect to one another. For example, the hinge mechanism 5310 could be a butt hinge; barrel hinge; flush hinge; piano hinge; spring; bistable spring; buckle; friction mechanism; sleeve that insert into a slot; or channel that interlocks with inserts. In some embodiments, the support member 5304 and the mounting member 5306 are a single piece of material. In some embodiments, a bistable spring or mechanism is used, where two stable states of the spring or mechanism orient the support member 5304 and the mounting member 5306 in the first and second positions.

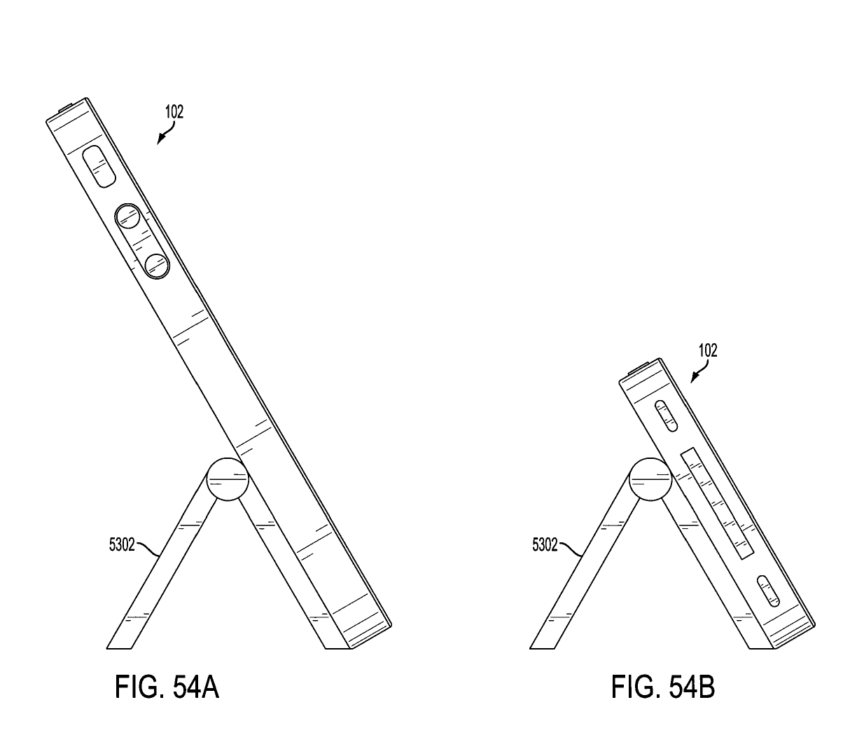

As shown in FIG. 54A, when the support accessory 5302 is attached to a surface 104 of a mobile electronic device case 102, and the support member 5304 is in the second operating position, the support accessory 5304 maintains the mobile electronic device case 102 in a semi-upright position when the case 102 is placed on a surface. FIG. 54A illustrates the support accessory 5302 supporting the mobile electronic device 102 case in a “portrait” orientation. FIG. 54B illustrates the support accessory 5302 supporting the mobile electronic device case 102 in a “landscape” orientation.

Turning back to FIG. 53C, in some embodiments, the support accessory 5302 has a handle 5312 that facilitates a user in moving the support member 5304 between the first collapsed position and the second operating position. In some embodiments, the handle 5312 is a recess between the support member 5304 and the mounting member 5306. In some embodiments, the recess is substantially the size of a fingernail.

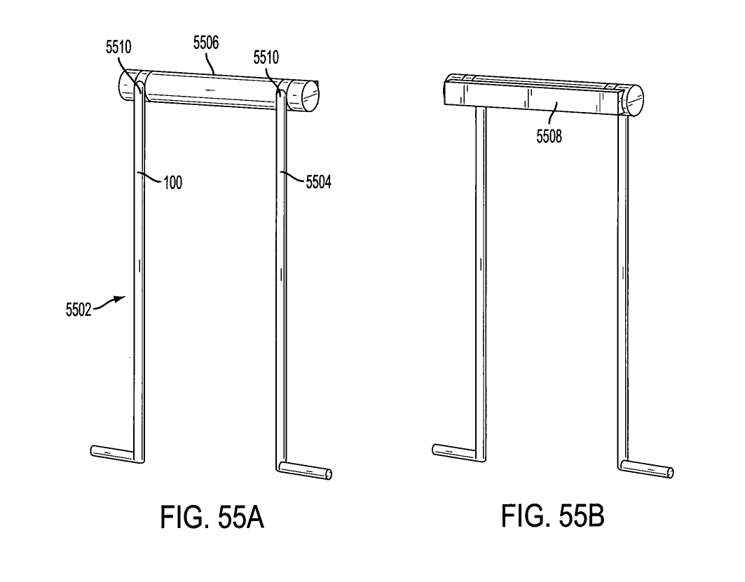

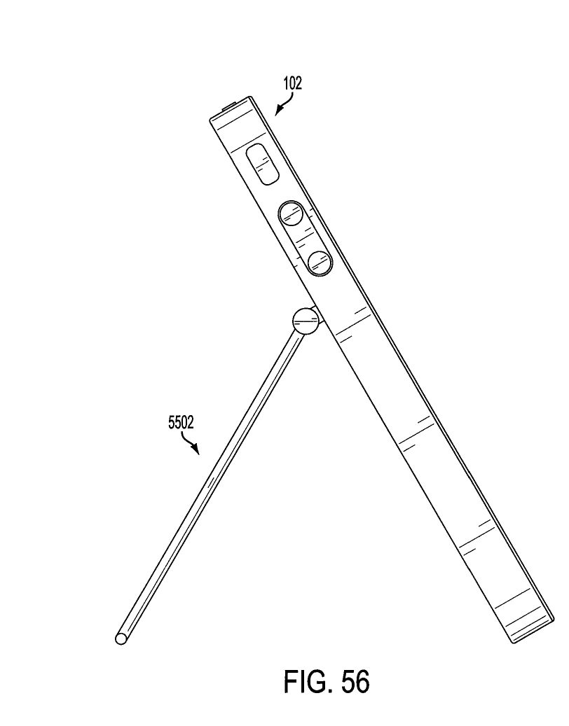

FIGS. 55 and 56 illustrate an additional embodiment 5502 of the support accessory described above, including support members 5504, a mounting member 5506, an attachment mechanism 5508, and a hinge mechanism 5510.

FIG. 56 illustrates the support accessory 5502 supporting the mobile electronic device 102 case in a “portrait” orientation.

In some embodiments, the support accessory allows a case to be supported without the case or the mobile electronic device touching the supporting surface. For example, the support accessory could include a support member, such as a tower or a tripod, and a mounting head. In some embodiments, the mounting head can swivel or gimbal with respect to the support member, such that the head (and an attached mobile electronic device) can be oriented in various positions. In some embodiments, the support member is a tripod with articulating legs. In some embodiments, the mounting head includes a mounting surface and a magnetic attachment component, such that a mobile electronic device case with a magnetic material back can be removably attached to the mounting head.

In some embodiments, the components of the support accessories (5002, 5302, and 5502) are made of any suitable material or combination of materials, including, but not limited to, plastic, elastomer, silicone, wood, metal, fiberglass, polymer, and/or rubber. The specific material or materials used may depend on the particular design chosen for the components of the support accessories (5002, 5302, 5502), and such design choices can be made without departing from the spirit of the invention.

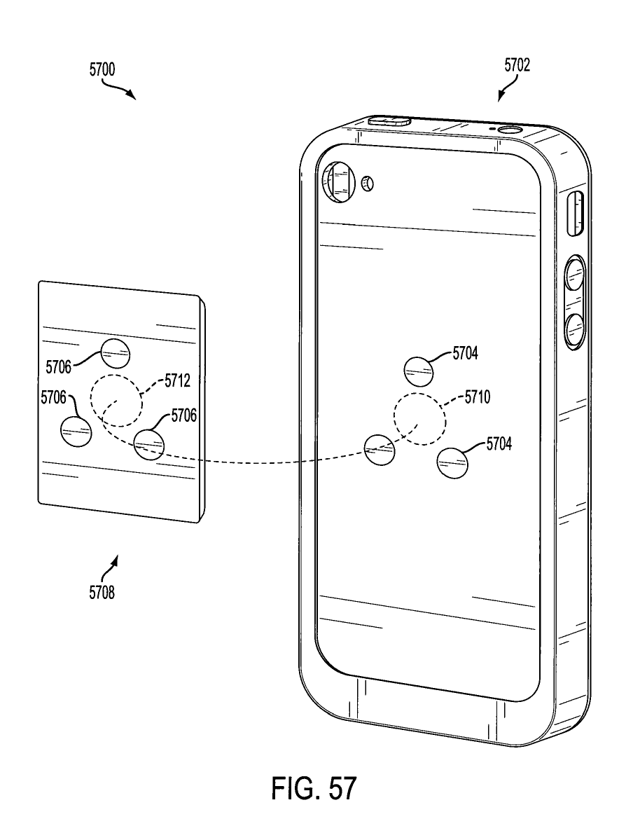

Attention is now directed to FIGS. 57-65, illustrating various embodiments of a connection system for mounting and/or connecting a mobile electronic device to an object external to the case.

FIG. 57 illustrates an embodiment of a mobile device connection system 5700. The connection system 5700 includes a case 5702 for a mobile electronic device. The case 5702 has a back that includes a first set of magnetic attachment elements 5704. The magnetic attachment elements 5704 are configured to removably attach the case 5702 to a corresponding set of second magnetic attachment elements 5706 attached to an object 5708 external to the case. The case 5702 has a first electrical interface 5710 for interfacing with a second electrical interface 5712 attached to the object 5708 external to the case.

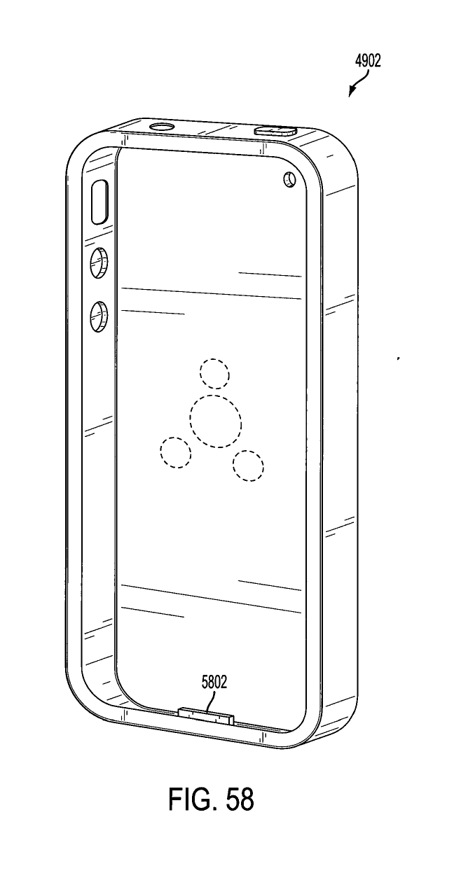

FIG. 58 illustrates a front view of the case 5702, showing a third electrical interface 5802 attached with the case 5702. The third electrical interface 5802 is configured to connect to a fourth electrical interface on a mobile electronic device (not shown). In some embodiments, the third electrical interface 5802 is provided so that a mobile electronic device can be brought into electrical communication with an object (via communication between the first and second electrical interfaces) without requiring any alteration to the mobile electronic device. In other words, the third electrical interface 5802 is configured to connect to an external connection port on a mobile electronic device, so that no components of the mobile electronic device need to be removed or replaced in order to facilitate an electrical connection between an object and the device.

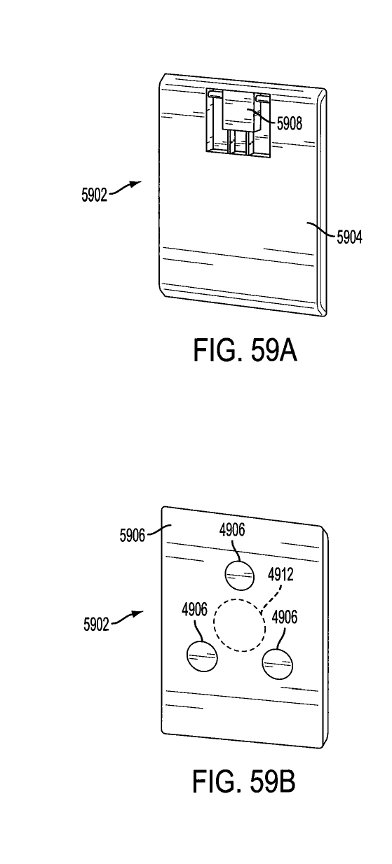

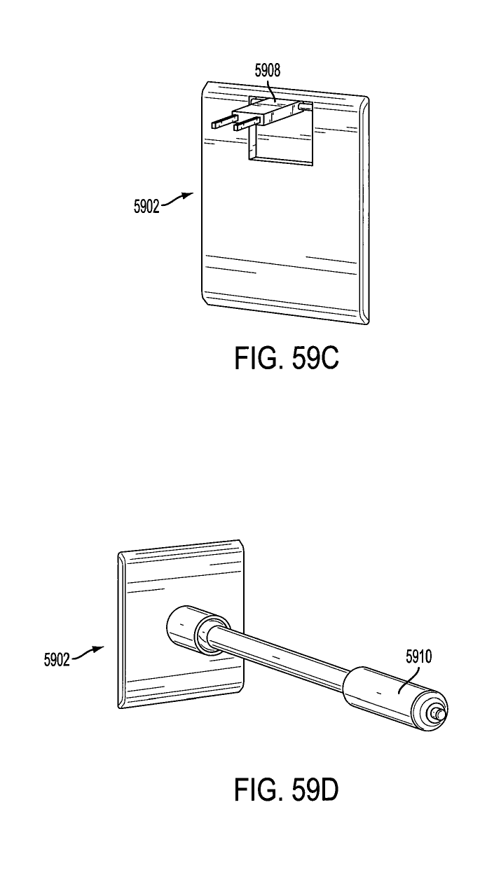

In some embodiments, the first electrical interface 5710 on the case 5702 and the second electrical interface 5712 on the object 5708 are inductive based interfaces. The second electrical interface 5712 (e.g., on an object 5708 that is a charger) will create an electromagnetic field in the vicinity of the interface. When the first electrical interface 5710 is in close proximity to the second electrical interface 5712, the electromagnetic field will induce an electrical current in the first electrical interface 5712. This current can then be delivered to a mobile electronic device via the third electrical interface 5802 within the case 5702. FIG. 59 illustrates an embodiment of the object 5708 where the object is a charger with an induction interface as described.

FIG. 59 shows an embodiment of the object external to the case in accordance with embodiments of present invention. In some embodiments, the external object is a charger 5902 for a mobile electronic device. The charger includes a housing 5904, a mounting surface 5906, and a plug 5908. The second set of magnetic attachment elements 5706 and the second electrical interface 5710 (described in detail above) are adjacent to the mounting surface 5906. In some embodiments, they are inside the housing 5904, and reside behind the mounting surface 5906. In some embodiments, they are embedded in the material of the mounting surface 5906. In some embodiments, the second set of magnetic attachment elements 5706 is mounted on the outside of the mounting surface 5906. One of skill in the art will understand that alternative combinations of the specific locations and configurations of the second set of magnetic attachment elements 5706 and the second electrical interface 5710 are possible without departing from the spirit of the invention.

As mentioned above, the object 5902 includes a plug 5908 for connection with an electrical outlet. The plug 5908 is hingably connected to the charging device, such that the plug 5908 has at least a first charging position (as shown in FIG. 59C) and a second storage position (as shown in FIG. 59A). When the plug is in the first charging position, the plug 5908 is positioned along an axis that is substantially perpendicular to a plane formed by the mounting surface 5906 of the object 5902. Thus, when the object 5902 is plugged into a wall outlet, for example, the mounting surface 5906 will be vertical to the ground. A user can then place a mobile electronic device case on the mounting surface 5906, and the case 5702 will be magnetically held to the mounting surface 5906. In some embodiments, the first and second sets of magnetic attachment elements 5704, 5706 are strong enough that a mobile electronic device will be securely held against the mounting surface 5906 regardless of the orientation of the object 5902 and the case 5702 relative to the ground. In some embodiments, the object 5902 can be plugged in upside-down, and the mobile electronic device (and case 5702) will still be securely held against the mounting surface 5906. In some embodiments, the plug is a cigarette lighter plug 5910, for connection to a cigarette lighter or an auxiliary power outlet in an automobile. FIG. 59C illustrates an embodiment where the object 5902 includes a cigarette lighter plug 5910.

Depending on certain specific design choices, it is possible to use different arrangements of magnets to ensure that the first and second electrical interfaces are correctly aligned with respect to one another when the mobile electronic device case is attached to the external object. For example, a number of discrete magnetic attachment elements can be positioned in specific orientations such that the device case and the object connect to one another in a predictable, repeatable location. Also, some embodiments use other alignment mechanisms in addition to or instead of specific orientations of magnetic attachment elements. These could include combinations of recesses and protrusions on the case and the accessory, or a recess in the back of the case, both of which are described in more detail above.

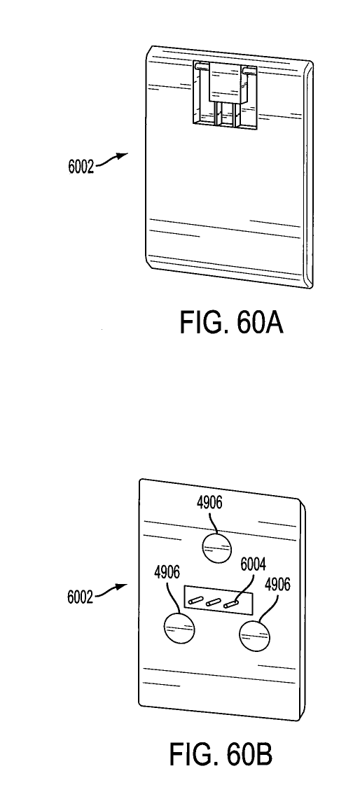

FIG. 60 illustrates an embodiment of the object where the object is a charger 6002. In some embodiments, the second electrical interface 6004 on the charger 6002 includes conductive connectors rather than an inductive connection. In these embodiments, the first electrical interface 5710 on the case includes conductive connectors for electrical connection to the second electrical interface 6002.

In some embodiments, the first set of magnetic attachment elements 5704 and the first electrical interface 5710 are positioned relative to each other in a first configuration. Also, the second set of magnetic attachment elements 5706 and the second electrical interface 5712 are positioned relative to one another in a configuration substantially similar to the first configuration. In some embodiments, the sets of magnetic attachment elements 5704, 5706 are configured to correspond to each other, so that when the first set of magnetic attachment elements 5704 is magnetically attached to the second set of magnetic attachment elements 5706, the first and second electrical interfaces 5710, 5712 are brought into electrical and/or inductive communication.

As shown in FIGS. 57-60, in some embodiments, the sets of magnetic attachment elements include three discrete magnetic attachment elements that are positioned on their respective objects (e.g., the object 5708 and the case 5702) to form an isosceles triangle. In some embodiments, the sets of magnetic attachment elements can form any shape that does not exhibit rotational symmetry. When positioned in this manner, the case 5702 can be designed to mount on the mounting surface (e.g., 5906) in only one orientation, thus ensuring that the first and second electrical interfaces 5710, 5712 are brought into correct alignment with one another. In some embodiments, another alignment mechanism is used to perform the same function. In some embodiments, the sets of magnetic attachment elements are positioned in other orientations that do exhibit rotational symmetry.

It is also possible to use the magnetic polarity as an alignment method to ensure that a device case (or a device) connects to an object (such as a charger) in a predictable, repeatable way. For example, it is well known that all magnets have a north pole and a south pole, and that opposite poles attract to one another, while similar poles repel one another. Thus, for magnets to be attracted to each other so that they physically hold to each other, the north pole of one magnet must be brought into proximity with the south pole of another magnet. Likewise, if north poles are brought into proximity with each other, the magnets will repel one another. It is possible, therefore, to design a magnetic attachment system where a mobile electronic device case and an object for connection to the case will attach to one another in a preferred way. While some designs will only allow attachment of the device case to the object in a single orientation or location, other configurations could be employed as well.

For example, a set of magnets or magnetic materials on an object and a corresponding case for mounting to the object could be arranged in a symmetrical shape, like a square. On the case, for example, three of the four sides or vertices of the square could present to the mounting surface a magnetic north pole, while the other side or vertex presents a south pole. The corresponding magnets on the object would have an inverted orientation of magnets. Thus, the polarity of the magnets will allow the case and the object to attract to one another only in one orientation. If a user attempted to mount the case to the object upside down, for instance, at least one of the sets of magnets would repel one another, and the case would not be properly or fully held to the object. In some embodiments, the magnets are selected to have attractive and repulsive forces such that the case will not attach at all when the polarities of the magnets are not properly aligned. One of skill in the art will recognize that various orientations of magnets, as well as various types of metals and magnetic materials can be used in the above described embodiments without departing from the spirit of the invention.

In some embodiments, when the first and second electrical interfaces are brought into electrical and/or inductive communication with each other, the third electrical interface 5802 on the mobile electronic device case 5702 is in electrical communication with the second electrical interface 5712 on the object 5708. Thus, electrical current can be transferred from the object 5708 to the third electrical interface 5802 that connects to a mobile electronic device (via an electrical interface on the device that is connected to the third electrical interface), and the mobile electronic device can be charged. In some embodiments, the object 5708 is a spare battery that can provide extra power to the mobile electronic device. In some embodiments, the spare battery has a set of interfaces and connection elements similar to those on the case 5702 (e.g., magnetic attachment elements 5704 and first electrical interface 5710), so that the case 5702, the battery, or the case 5702 with the battery attached can be connected to the charger to be charged.

In some embodiments, when the electrical interfaces 5710 and 5712 are brought into electrical communication, they carry data signals, bringing a mobile electronic device into data communication with a second electronic device. In some embodiments, the second electronic device is a computer, speaker, speaker set, alarm clock, display screen, or image projector, or a “dock” for any of these types of devices.

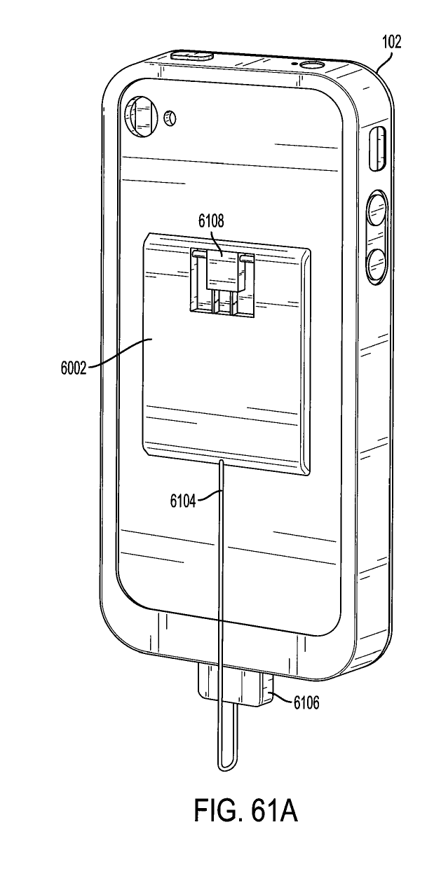

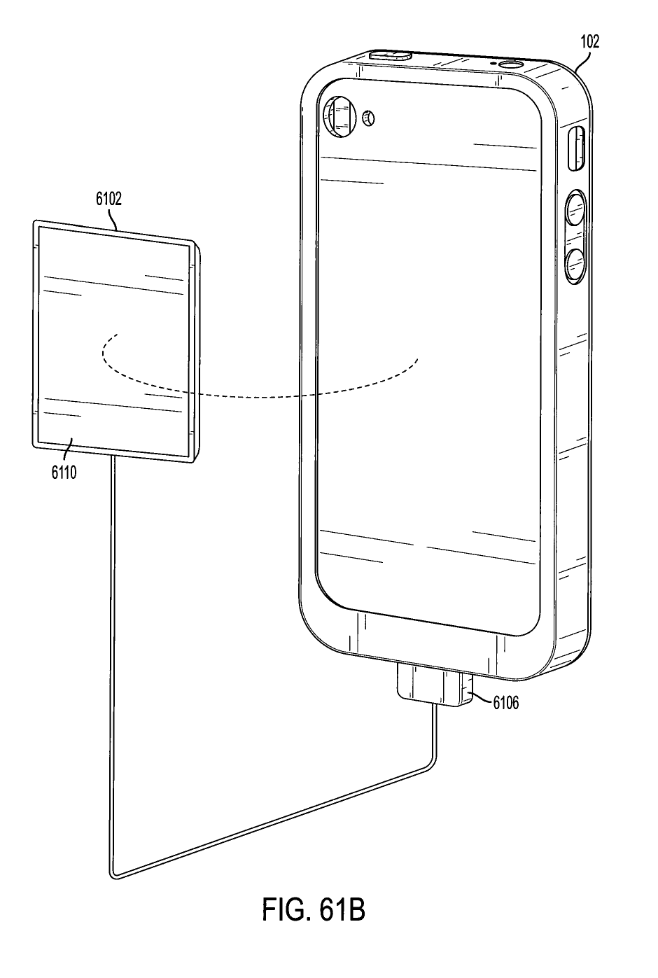

FIG. 61 illustrates an embodiment of the mobile device connection system in accordance with the present invention. The mobile device connection system includes a charger 6102 with a plug 6108 for connecting the charger 6102 to a power source, and a magnetic attachment element 6110. The plug 6108 is hingably connected to the charger 6102 such that the plug 6108 has a first charging position and a second storage position (similar to the plug 5908 as shown in FIGS. 59C and 59A, described in greater detail above.) The charger 6102 also has a cable 6104 with a first electrical interface 6106 at one end for connection to a mobile electronic device that has a second electrical interface. The cable 6104 and the first electrical interface 6106 are configured to transmit electric current to the mobile electronic device when the cable 6104 is connected to the mobile electronic device via the first electrical interface 6106. In some embodiments, the plug 6108 is configured to fit in a standard AC electrical outlet. In some embodiments, the plug 6108 is a USB plug. In some embodiments, the plug is not hingably attached to the object, but is attached via a length of flexible cable.

In some embodiments, the magnetic attachment element 6110 is made up of either magnets or magnetic materials. Accordingly, a case for a mobile electronic device that has a metal back, for instance, can be attached to the charger by means of a magnetic attraction between the magnet/magnetic material and the metal back. Of course, one of skill in the art will recognize that there are many combinations of magnets and/or magnetic materials that can be employed in the present invention to attach a mobile electronic device to a charger 6102. Furthermore, many types of attachment mechanisms can be employed in addition to or instead of magnets, as described in more detail above with reference to FIG. 1. Furthermore, one of skill in the art will recognize that any object 5708 (e.g., a charger, speaker set, computer, etc.) can advantageously use any combination of the above described mounting techniques or electrical interface types. For example, in some embodiments, the charger 6102 is an auxiliary speaker set for a mobile electronic music player. The object may also be a mount or dock that contains a battery or other electricity storing device that will charge or power the mobile electronic device. One of skill in the art will recognize that an object as described above can omit the plug without departing from the spirit of the invention.

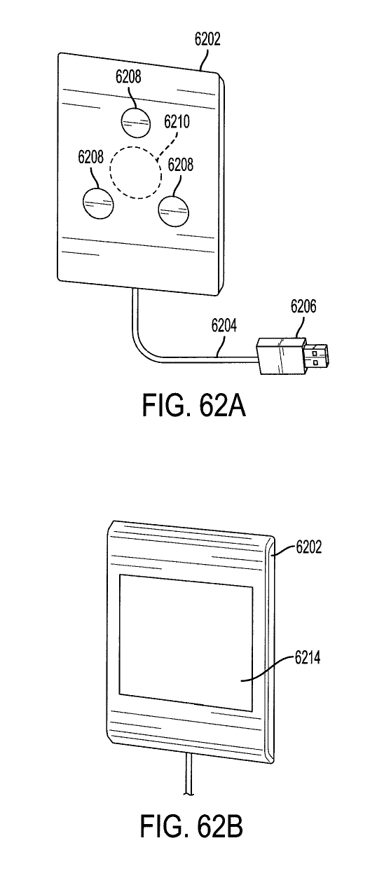

FIG. 62 illustrates an embodiment of the mobile device connection system in accordance with the present invention. Similar to the charger discussed in relation to FIG. 59, the charger 6202 can be designed for use in conjunction with the case 5702. In some embodiments, the charger 6202 includes a second set of magnetic attachment elements 6208 and a second electrical interface 6210. The set of attachment mechanisms and the second electrical interface are described at length above, and the details are not repeated here. In some embodiments, charger 6202 includes a cable 6204 with a plug 6206, where the plug 6206 can be connected with a power sources. In some embodiments, the plug 6206 is a USB plug for connection to a USB receptacle. In some embodiments, the plug 6206 is a plug for a standard wall outlet.

In some embodiments, the charger 6202 includes an additional attachment mechanism 6214 for connecting the charger 6202 to another surface. For instance, attachment mechanism 6214 can attach the charger 6202 to the side of a computer monitor. The attachment mechanism 6214 can be any of a variety of attachment mechanisms, including snaps, hook and loop mechanisms, Velcro, adhesives, magnets and/or magnetic materials, suction devices, van der Waals force attachment mechanisms, buckles, sleeves that insert into slots, pegs that are inserted into holes, hinges, and/or snaps.

In some embodiments, the charger 6202 does not have the electrical interface 6210, but instead comprises an additional cable that is configured to connect directly to a mobile electronic device. In these embodiments, the charger 6202 does not require the user of a case such as case 5702 (which includes a first electrical interface 5710 for interfacing with a second electrical interface). Rather, a mobile electronic device case that has a magnetic material component (such as a metal back) can be attached to the charger 6202 by means of a magnetic attraction between the second set of magnetic attachment elements 6208 (or an alternative magnetic attachment mechanism) and the magnetic material component. Further description of various magnetic attachment mechanisms are described in detail elsewhere in the specification, and are not recited in detail here. It should be noted that in the above discussion, the charger 6202 can refer to the entire accessory described, or any individual part of the accessory described.

The connection system described above for connecting a mobile electronic device to another object (such as a charger or speaker set) can be advantageously employed in automobile mounts and chargers as well. For example, a magnetic mounting system as described with relation to any of FIGS. 57-62 can be incorporated into any of a variety of automobile-based mounting systems. Furthermore, any of the electrical connection systems described above, e.g., case-mounted electrical interfaces shown in FIG. 57, or cable connections as shown in FIG. 61, can also be incorporated into those automobile-based mounting systems.

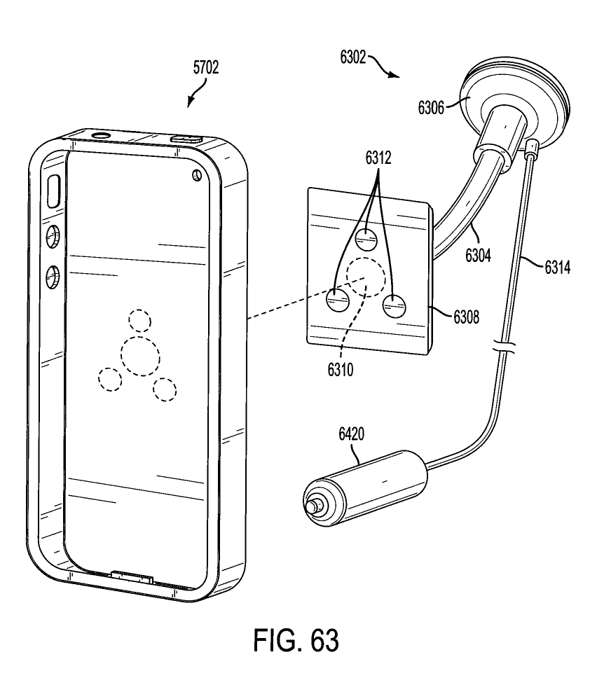

FIG. 63 illustrates an embodiment where the connection system is incorporated into a vehicle mount 6302. It should be noted that a car can be any vehicle, including a truck, plane, motorcycle, scooter, SUV, boat, etc. The vehicle mount 6302 includes a case mounting head 6308, a mounting arm 6304, and a vehicle mounting base 6306. The case mounting head 6308 may contain a second set of magnetic attachment elements 6312 and a second electrical interface 6310 for connection to the respective components of the case 5702. Details of these connection mechanisms and interfaces are described above and are not repeated here. The vehicle mounting base 6306 can be configured to mount to a vehicle in a variety of ways. In some embodiments, the base 6306 is a suction cup for mounting to a smooth surface, such as a window, dash board, or mirror. In some embodiments, the base 6306 is adhesive and can be stuck to any surface. In some embodiments, the base 6306 is made of flexible material, such as a rubber, elastomer, leather, and/or other material so that the base 6306 can mount more securely to contoured surfaces, like a dash board or center console of a vehicle. In some embodiments, the base is a rigid member with holes that can be bolted to some part of a vehicle. In some embodiments, the base is any other mechanism that attaches or stabilizes the vehicle mount 6302 to a vehicle, such as a cup shaped member for insertion into a cup holder, a clip, a sandbag, and/or a beanbag.

In some embodiments, the mounting arm 6304 is a flexible member that connects the vehicle mounting base 6306 to the case mounting head 6308. The flexible member 6304 is a wire, flexible conduit, spring, and/or any other type of member that allows a user to position the case mounting head 6308 in a convenient viewing or storage location. In some embodiments, the flexible member 6304 is able to retain a shape when it is bent into a position by a user.

In some embodiments, the vehicle mount 6302 includes a cable 6314 and a plug 6320 configured to supply power to a mobile electronic device through the case 5702 and the electrical interface 6310. In some embodiments, the vehicle mount 6302 has bare wire ends instead of a plug so that the cable 6314 can be hard-wired to the vehicle's electrical system. Alternatively, the vehicle mount 6302 can be configured without the electrical interface 6310 and cable 6314 so that the mount is simply a mount with a magnetic case mounting head 6308. In some embodiments, the vehicle mount 6302 includes a cable for connection directly to a mobile electronic device. Thus, the vehicle mount 6302 can include charging functionality without the need of a special case, such as 5702.

It should be noted that the electrical connections described above may also include electrical data connections so that a mobile electronic device can be brought into data communication with electrical systems and computers in a vehicle. For instance, an audio output signal from a mobile electronic device can be routed to the speakers of a car. Furthermore, a vehicle may have a built-in microphone, which can be routed to a mobile device (such as a telephone) as an audio input signal. Information from the vehicle's onboard computer systems could also be communicated to a device. For instance, a mobile device running navigation software could receive information from the vehicle such as the vehicle's speed, fuel level, odometer values, or even vehicle diagnostic information. Furthermore, other types of devices or applications could utilize a data connection in accordance with embodiments of the invention, including vehicle diagnostic code readers/analyzers, vehicle performance recorders, and the like.

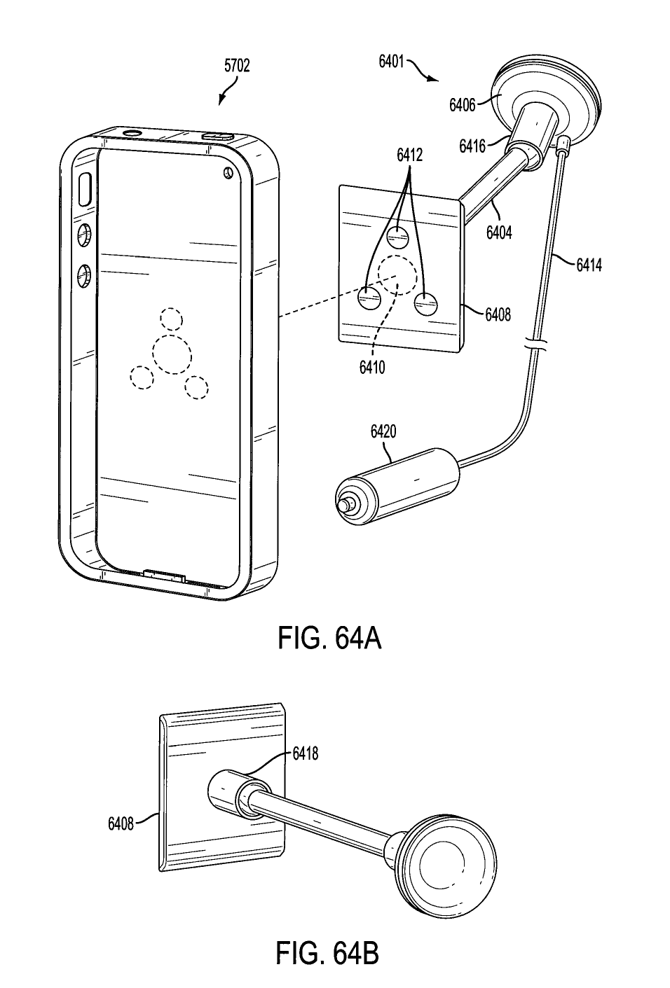

FIG. 64 illustrates another embodiment where the connection system is incorporated into a vehicle mount 6402. Vehicle mount 6402 includes a case mounting head 6408, a mounting arm 6404, and a vehicle mounting base 6406. The case mounting head 6308 may contain a second set of magnetic attachment elements 6412 and a second electrical interface 6410 for connection to the respective components of the case 5702. Details of these connection mechanisms and interfaces are described above and are not repeated here. The vehicle mounting base 6406 may be configured to attach the vehicle mount 6402 to the vehicle in a variety of ways, as discussed above with reference to FIG. 63.

In the embodiment shown in FIG. 64, the mounting arm 6404 is movably connected with the mounting base 6406 with a ball-and-socket mechanism. In some embodiments, the mounting base 6406 includes a socket 6416 that receives an end of the mounting arm 6404. In some embodiments, the case mounting head 6408 is also movably connected with the mounting arm 6404 with a ball and socket mechanism. In some embodiments, the mounting head 6408 includes a socket 6418 that receives an end of the mounting arm 6404. By using two ball-and-socket mechanisms to connect the mounting arm 6404 to the mounting head 6408 and mounting base 6406, the mounting head can be moved into various user-selected positions so a user can position a mobile electronic device in a convenient viewing or storage location. The ball-and-socket mechanism may also be configured so that the joints are fairly stiff, so that the mounting head 6408 is mostly stationary with respect to the mounting base 6406 during normal vehicle use conditions, but flexible enough so that a user can easily reposition the mounting head 6408 or the mounting arm 6404 with his or her hands. In some embodiments, the ball-and-socket mechanisms have locking mechanisms to allow a user to increase or decrease the stiffness of a particular joint. It should also be noted that the ball-and-socket mechanisms can be inverted, such that the mounting arm 6404 includes one or more sockets, and the mounting base 6406 and/or the mounting head 6408 include balls. Furthermore, while ball-and-socket joints are described, one of skill in the art will recognize that other joints or connectors can be employed without departing from the spirit of the invention. For example, the vehicle mount 6406 could use hinges, flexible conduit, wires, and/or springs to achieve the same functionality.

In some embodiments, vehicle mount 6402 includes a cable 6414 and a plug 6420, similar to those described above with reference to FIG. 63. The various electrical interfaces and wiring options for vehicle mounts are discussed in greater detail above with reference to FIG. 63, and are not repeated here, though they are equally applicable to vehicle mount 6402.

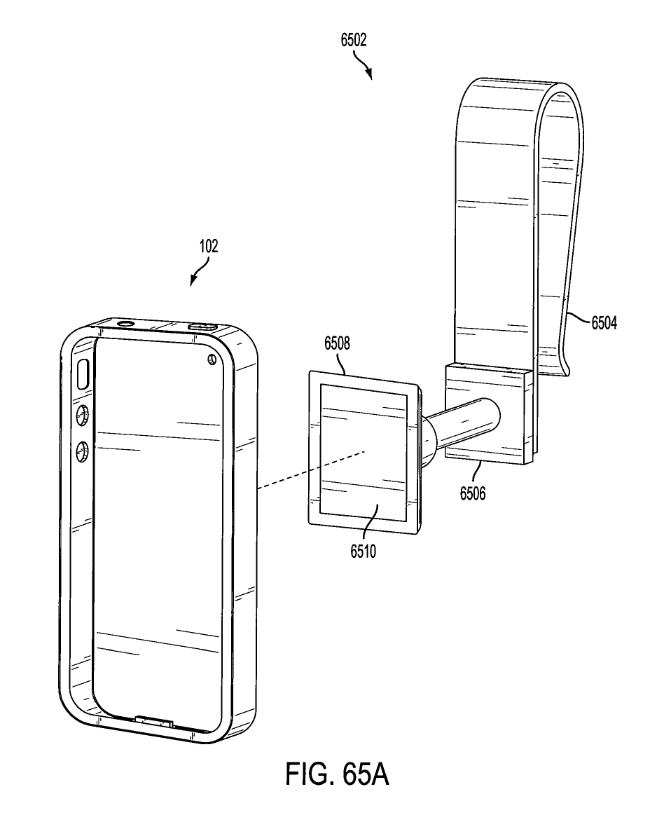

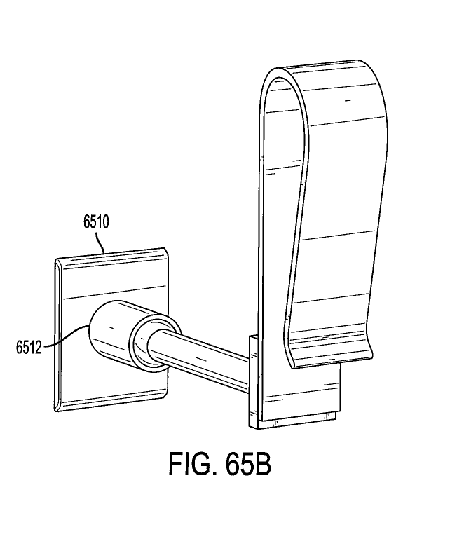

FIG. 65 illustrates an embodiment where the connection system is incorporated into vehicle mount 6502. Vehicle mount 6502 includes a clip 6504, a flexible connector 6506, a mounting head 6508, and a magnetic attachment element 6510. In some embodiments, the clip 6504 is configured to connect the vehicle mount 6502 to some part of a vehicle, such as a visor, rear view mirror, ashtray, and/or any other convenient location. In some embodiments, the clip 6504 is a single piece of resilient material that grips a portion of a vehicle interior due to the spring effect of the clip material. In some embodiments, the clip 6504 has at least one hinge and at least one spring. In some embodiments, the clip 6504 can be small so that it can be attached to a fin of an air conditioning vent. One of skill in the art will recognize that various types and sizes of clips can be used without departing from the spirit of the invention.

In some embodiments, the flexible connector 6506 is a ball-and-socket joint, where the mounting head 6508 includes a socket 6512 for mounting onto a ball portion of the flexible connector 6506. Various configurations of ball-and-socket joints can be used for the flexible connector 6506, and are described in more detail above with reference to FIGS. 63 and 64. Furthermore, any of the flexible materials or members described above may be utilized in embodiments of the vehicle mount 6506 so that the mounting head 6510 can be positioned in a convenient viewing or storage location or position.

Furthermore, while the vehicle mount 6502 is not shown with any electrical interfaces or cables, it should be understood that any combination of the above mentioned interfaces, connectors, plugs, and cables can be used in embodiments without departing from the spirit of the invention. Finally, it should be noted that the mounting systems herein described can be made of any suitable material or combination of materials, including metal, plastic, polymer, fiberglass, carbon fiber, and/or any other material meeting the design needs of the particular mounting system component.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

We claim:

1. A mobile electronic device accessory system, comprising:
a mobile electronic device case with a surface and a first attachment mechanism;
an accessory, the accessory comprising a second attachment mechanism, and being removably attached to the surface of the mobile electronic device case.

2. An accessory-holding case for a mobile electronic device comprising:
a case with a back, wherein the back has a recessed portion defined by a shoulder, the recessed portion configured to receive an accessory therein, and
an attachment mechanism for removably attaching the accessory to the mobile electronic device case.

3. A method of using an accessory for a mobile electronic device case, comprising:
providing a mobile electronic device case with a surface and a first attachment mechanism,
providing an accessory with a second attachment mechanism, the accessory configured to be removably attached to a surface of the mobile electronic device case;
removably attaching the accessory to the surface of the mobile electronic device case via the first and second attachment mechanisms.

4. The mobile electronic device accessory system of claim 1, wherein the accessory is a carrying accessory.

5. The mobile electronic device accessory system of claim 3, wherein the carrying accessory is configured to fit substantially within an area defined by the surface of the mobile electronic device case.

6. The mobile electronic device accessory system of claim 3, wherein the carrying accessory is configured to at least partially contain at least one item.

7. The mobile electronic device accessory system of claim 3, wherein the carrying accessory is thinner than the thickness of the mobile electronic device case.

8. The mobile electronic device accessory system of claim 3, wherein the carrying accessory is a card holder.

9. The mobile electronic device accessory system of claim 3, wherein the carrying accessory is a money clip.

10. The mobile electronic device accessory system of claim 3, wherein the carrying accessory is a key holder.

11. The mobile electronic device accessory system of claim 3, wherein the carrying accessory is a photograph holder.

12. The mobile electronic device accessory system of claim 3, wherein the carrying accessory is a coin purse.

13. The mobile electronic device accessory system of claim 3, wherein the carrying accessory comprises a window.

14. The mobile electronic device accessory system of claim 3, wherein the carrying accessory is at least partially made of any of the following types of materials: leather; plastic; elastomer; silicone; wood; metal; fabric; or rubber.

15. The mobile electronic device accessory system of claim 3, wherein the first and second attachment mechanisms are selected from the group consisting of: magnet(s); magnetic material(s); Velcro; adhesives; suction devices; friction mechanisms; buckles; hinges; springs; bistable springs; sleeves that insert into slots; pegs that insert into holes snaps; buttons; and a van der Waals force attachment mechanism.

16. The mobile electronic device accessory system of claim 3, wherein the second attachment mechanism comprises at least one magnet and/or magnetic material.

17. The mobile electronic device accessory system of claim 3, wherein the first attachment mechanism is at least one magnetic material component of the mobile electronic device case.

18. The mobile electronic device accessory system of claim 3, wherein the first attachment mechanism is a back of the mobile electronic device case that is composed at least partially of magnetic material.

19. The mobile electronic device accessory system of claim 18, wherein the magnetic material is magnetic metal.

20. The mobile electronic device accessory system of claim 18, wherein the magnetic material is ferromagnetic material and/or paramagnetic material.

21. The mobile electronic device accessory system of claim 1, wherein the accessory is a mirror.

22. The mobile electronic device accessory system of claim 21, wherein the mirror is configured to fit substantially within an area defined by the surface of the mobile electronic device case.

23. The mobile electronic device accessory system of claim 21, wherein the second attachment mechanism comprises at least one magnet and/or magnetic material.

24. The mobile electronic device accessory system of claim 21, wherein the first attachment mechanism is at least one magnetic material component of the mobile electronic device case.

25. The mobile electronic device accessory system of claim 21, wherein the first attachment mechanism is a back of the mobile electronic device case that is composed at least partially of magnetic material.

26. The mobile electronic device accessory system of claim 25, wherein the magnetic material is magnetic metal.

27. The mobile electronic device accessory system of claim 25, wherein the magnetic material is ferromagnetic material and/or paramagnetic material.

28. The mobile electronic device accessory system of claim 1, wherein the accessory is a flashlight comprising at least one light source.

29. The mobile electronic device accessory system of claim 28, wherein the flashlight is configured to fit substantially within an area defined by the surface of the mobile electronic device case.

30. The mobile electronic device accessory system of claim 28, wherein the at least one light source is selected from a group consisting of Light Emitting Diodes, lasers, and incandescent bulbs.

31. The mobile electronic device accessory system of claim 28 comprising an additional light source, wherein the at least one light source is a Light Emitting Diode and the additional light source is a laser.

32. The mobile electronic device accessory system of claim 28, wherein the first and second attachment mechanisms are selected from the group consisting of: magnets; magnetic material(s); Velcro; adhesives; suction devices; friction mechanisms; buckles; hinges; springs; bistable springs; sleeves that insert into slots; pegs that insert into holes snaps; buttons; and a van der Waals force attachment mechanism.

33. The mobile electronic device accessory system of claim 28, wherein the second attachment mechanism comprises at least one magnet and/or magnetic material.

34. The mobile electronic device accessory system of claim 28, wherein the first attachment mechanism is at least one magnetic material component of the mobile electronic device case.

35. The mobile electronic device accessory system of claim 28, wherein the first attachment mechanism is a back of the mobile electronic device case that is composed at least partially of magnetic material.

36. The mobile electronic device accessory system of claim 35, wherein the magnetic material is magnetic metal.

37. The mobile electronic device accessory system of claim 35, wherein the magnetic material is ferromagnetic material and/or paramagnetic material.

38. The mobile electronic device accessory system of claim 1, wherein the accessory is a notepad comprising a mounting surface, the second attachment mechanism connected with the mounting surface.

39. The mobile electronic device accessory system of claim 38, wherein the notepad is configured to fit substantially within an area defined by the surface of the mobile electronic device case

40. The mobile electronic device accessory system of claim 38, further comprising a retaining member for securing the pages to the mounting surface.

41. The notepad accessory of claim 39, wherein the retaining member is a strap.

42. The mobile electronic device accessory system of claim 38, further comprising a semi-rigid cover connected with the mounting surface.

43. The notepad accessory of claim 42, further comprising a strap member for securing the cover and the pages to the mounting surface.

44. The mobile electronic device accessory system of claim 38, wherein the first and second attachment mechanisms are selected from the group consisting of: magnets; magnetic material(s); Velcro; adhesives; suction devices; friction mechanisms; buckles; hinges; springs; bistable springs; sleeves that insert into slots; pegs that insert into holes snaps; buttons; and a van der Waals force attachment mechanism.

45. The mobile electronic device accessory system of claim 38, wherein the second attachment mechanism comprises at least one magnet and/or magnetic material.

46. The mobile electronic device accessory system of claim 38, wherein the first attachment mechanism is at least one magnetic material component of the mobile electronic device case.

47. The mobile electronic device accessory system of claim 38, wherein the first attachment mechanism is a back of the mobile electronic device case that is composed at least partially of magnetic material.

48. The mobile electronic device accessory system of claim 47, wherein the magnetic material is magnetic metal.

49. The mobile electronic device accessory system of claim 47, wherein the magnetic material is ferromagnetic material and/or paramagnetic material.

50. The mobile electronic device accessory system of claim 1, wherein the accessory is a pen.

51. The mobile electronic device accessory system of claim 50, wherein the pen is a ball point pen, felt tipped pen, fountain pen, gel pen, roller ball pen, marker, and/or highlighter.

52. The mobile electronic device accessory system of claim 1, wherein the accessory is a pencil.

53. The mobile electronic device accessory system of claim 1, wherein the accessory is a spring clip.

54. The mobile electronic device accessory system of claim 53, wherein the spring clip comprises:
a first and a second opening tab;
a first and a second gripping tab;
a spring connected with the first and second opening tabs and the first and second gripping tabs, and biasing the first and second gripping tabs in a closed position, such that when the gripping tabs are in the closed position, the first and second gripping tabs are nearer to one another than the first and second opening tabs; and
a flexible cover connected with the first and second opening tabs and spanning a gap between the first opening tab and the second opening tab.

55. The mobile electronic device accessory system of claim 53, wherein the spring clip is thinner than the thickness of the mobile electronic device case.

56. The mobile electronic device accessory system of claim 53, wherein the first and second attachment mechanisms are selected from the group consisting of: magnets; magnetic material(s); Velcro; adhesives; suction devices; friction mechanisms; buckles; hinges; springs; bistable springs; sleeves that insert into slots; pegs that insert into holes snaps; buttons; and a van der Waals force attachment mechanism.

57. The mobile electronic device accessory system of claim 53, wherein the second attachment mechanism comprises at least one magnet and/or magnetic material.

58. The mobile electronic device accessory system of claim 53, wherein the first attachment mechanism is at least one magnetic material component of the mobile electronic device case.

59. The mobile electronic device accessory system of claim 58, wherein the first attachment mechanism is a back of the mobile electronic device case that is composed at least partially of magnetic material.

60. The mobile electronic device accessory system of claim 59, wherein the magnetic material is magnetic metal.

61. The mobile electronic device accessory system of claim 59, wherein the magnetic material is ferromagnetic material and/or paramagnetic material.

62. The mobile electronic device accessory system of claim 53, wherein the spring clip is at least partially covered by a flexible material.

63. The mobile electronic device accessory system of claim 1, wherein the accessory is a tape measure.

64. The mobile electronic device accessory system of claim 63, wherein the tape measure is configured to fit substantially within an area defined by the surface of the mobile electronic device case.

65. The mobile electronic device accessory system of claim 63, wherein the first and second attachment mechanisms are selected from the group consisting of: magnets; magnetic material(s); Velcro; adhesives; suction devices; friction mechanisms; buckles; hinges; springs; bistable springs; sleeves that insert into slots; pegs that insert into holes snaps; buttons; and a van der Waals force attachment mechanism.

66. The mobile electronic device accessory system of claim 63, wherein the second attachment mechanism comprises at least one magnet and/or magnetic material.

67. The mobile electronic device accessory system of claim 63, wherein the first attachment mechanism is at least one magnetic material component of the mobile electronic device case.

68. The mobile electronic device accessory system of claim 67, wherein the first attachment mechanism is a back of the mobile electronic device case that is composed at least partially of magnetic material.

69. The mobile electronic device accessory system of claim 68, wherein the magnetic material is magnetic metal.

70. The mobile electronic device accessory system of claim 68, wherein the magnetic material is ferromagnetic material and/or paramagnetic material.

71. The mobile electronic device accessory system of claim 1, wherein the accessory is a cable winder.

72. The mobile electronic device accessory system of claim 71, wherein the cable winder comprises:
a front retaining member;
a mounting member; and
a wrapping shaft.

73. The mobile electronic device accessory system of claim 72, wherein the front retaining member comprises a cable retaining mechanism for receiving and holding a portion of a cable.

74. The mobile electronic device accessory system of claim 73, wherein the cable retaining mechanism is a slot in the front retaining member.

75. The mobile electronic device accessory system of claim 72, wherein the mounting member and the wrapping shaft are the same structural component.

76. The mobile electronic device accessory system of claim 72, wherein the front retaining member is removable from the mounting member.

77. The mobile electronic device accessory system of claim 72, wherein the wrapping shaft is removable from the mounting member.

78. A flat multiple tool holder accessory for connection to a mobile electronic device case, comprising:
a housing configured to fit substantially within an area defined by a surface of the mobile electronic device case, the housing defining at least one opening and at least one internal chamber configured to enclose at least a portion of at least one instrument;
an attachment mechanism connected with the housing for removably attaching the housing to the surface of the mobile electronic device case.

79. The flat multiple tool holder accessory of claim 78, wherein the at least one instrument is selected from the group consisting of: screwdrivers; tweezers; toothpicks; scissors; pliers; a key; knifes; blades; reamers; pins; allen wrenches; torx wrenches; files; saws; magnifying glasses; rulers; flashlights; corkscrews; pins; needles; bottle openers; wire cutters; wire strippers; chisels; can openers; digital storage devices; divot repairers; golf ball markers; marlin-spikes; fish scalers; hook disgorgers; and cigar cutters.

80. The flat multiple tool holder accessory of claim 78, wherein the attachment mechanism is selected from the group consisting of: magnets; magnetic material(s); Velcro; adhesives; suction devices; friction mechanisms; buckles; hinges; springs; bistable springs; sleeves that insert into slots; pegs that insert into holes snaps; buttons; and a van der Waals force attachment mechanism.

81. A flat multi-tool comprising a plurality of tools in combination, and having a peripheral outer edge that is configured to fit substantially within an area defined by a surface of a mobile electronic device case, the improvement comprising:
at least one attachment mechanism attached to a first surface of the multi-tool for removably attaching the multi-tool to a surface of a mobile electronic device case.

82. The flat multi-tool of claim 81, wherein the plurality of tools is selected from a group comprising: a ruler; a can opener; a bottle opener; a blade; a screwdriver; a saw; a pry-tool; a knife; and a wrench.

83. The flat multi-tool of claim 81, wherein the attachment mechanism is selected from the group consisting of: magnets; magnetic material(s); Velcro; adhesives; suction devices; friction mechanisms; buckles; hinges; springs; bistable springs; sleeves that insert into slots; pegs that insert into holes snaps; buttons; and a van der Waals force attachment mechanism.

84. A flat multi-tool accessory system comprising:
a mobile electronic device case, the case comprising:
a back with recessed portion defined by a shoulder; and
a first attachment mechanism; and
a flat multi-tool comprising:
a plurality of tools in combination; and
a peripheral outer edge configured to fit within the recess in the back of the mobile electronic device case.

85. A digital storage device for connection to a mobile electronic device case, comprising:
a body configured to fit substantially within an area defined by a surface of the mobile electronic device case;
a re-programmable, non-volatile flash memory element with an interface connector for connecting the digital storage device with a computer;
an attachment mechanism connected with the body for removably attaching the digital storage device to the surface of the mobile electronic device case.

86. The digital storage device of claim 85, wherein the interface connector is a Universal Serial Bus interface connector.

87. The digital storage device of claim 85, further comprising a cover.

88. The digital storage device of claim 87, wherein the cover is slidably attached with the body, the cover having a first open position and a second closed position, wherein when in the first open position, the interface connector is exposed to allow for the interface connector to be connected with the computer.

89. The digital storage device of claim 88, wherein the cover has a retaining mechanism such that when the cover is in the second closed position, the cover is preferentially maintained in the second closed position.

90. The digital storage device of claim 87, wherein the retaining mechanism comprises a protrusion and a recess, where the recess receives the protrusion therein when the cover is in the second closed position.

91. The digital storage device of claim 85, wherein the attachment mechanism is selected from the group consisting of: magnets; magnetic material(s); Velcro; adhesives; suction devices; friction mechanisms; buckles; hinges; springs; bistable springs; sleeves that insert into slots; pegs that insert into holes snaps; buttons; and a van der Waals force attachment mechanism.

92. A ruler accessory for connection to a mobile electronic device case, comprising:
a ruler configured to fit substantially within an area defined by a surface of the mobile electronic device case;
an attachment mechanism attached with the ruler for removably attaching the ruler to the surface of the mobile electronic device case.

93. The ruler accessory of claim 92, wherein the ruler comprises a first segment and a second segment, and at least one joint rotatably connecting the first and second segment such that the ruler has at least a first position and a second position, wherein when the ruler is in the first position, the ruler is at least partially collapsed and fits completely within an area defined by the surface of the mobile electronic device.

94. The ruler accessory of claim 92, wherein the attachment mechanism is selected from the group consisting of: magnets; magnetic material(s); Velcro; adhesives; suction devices; friction mechanisms; buckles; hinges; springs; bistable springs; sleeves that insert into slots; pegs that insert into holes snaps; buttons; and a van der Waals force attachment mechanism.

95. An audible alarm accessory for connection to a mobile electronic device case, comprising:
a housing configured to fit substantially within an area defined by a surface of the mobile electronic device case;
a magnetic attachment mechanism for removably connecting the audible alarm to the surface of the mobile electronic device case;
a speaker;
a control button; and
an electronic controller configured to cause the speaker to produce an audible sound from the speaker.

96. The audible alarm accessory of claim 95, wherein the electronic controller is configured to receive a wireless signal and cause the speaker to produce an audible sound when the electronic controller receives the wireless signal.

97. The audible alarm accessory of claim 95, wherein the electronic controller is configured to cause the speaker to emit an audible sound from the speaker when the control button is pressed.

98. The audible alarm accessory of claim 97, wherein the audible sound is electronic controller is configured to cause the speaker to emit an audible sound from the speaker when the control button is pressed.

99. The audible alarm accessory of claim 95, wherein the magnetic attachment element is at least one magnet and/or magnetic material.

100. The audible alarm accessory of claim 95, wherein the surface of the mobile electronic device case is made of a magnetic material.

101. The audible alarm accessory of claim 100, wherein the magnetic material is magnetic metal.

102. The audible alarm accessory of claim 100, wherein the magnetic material is ferromagnetic material and/or a paramagnetic material.

103. A support accessory for supporting a mobile electronic device case, comprising:
a support member; and
a magnetic attachment element attached with the support member for removably attaching the support accessory in a supporting position to a surface of the mobile electronic device case.

104. The support accessory of claim 103, wherein when attached to the surface of the mobile electronic device case in the supporting position, the support member is configured to maintain the mobile electronic device case in at least one semi-upright position.

105. The support accessory of claim 103, wherein the support member comprises:
a first side;
a second side substantially parallel to the first side;
a third side with at least one magnetic attachment element and forming a beveled surface between the first and second sides, such that when the third side is attached with the surface of the mobile electronic device case, the support member is magnetically held in the supporting position.

106. The support accessory of claim 105, wherein one of the first or second sides comprises a magnetic attachment element for mounting the support member in a stored position on the surface of the mobile electronic device.

107. The support accessory of claim 103, wherein the magnetic attachment element is at least one magnet and/or magnetic material.

108. The support accessory of claim 103, wherein the surface of the mobile electronic device case is made of a magnetic material.

109. The support accessory of claim 109, wherein the magnetic material is magnetic metal.

110. The support accessory of claim 109, wherein the magnetic material is ferromagnetic material and/or a paramagnetic material.

111. A support accessory for supporting a mobile electronic device case, comprising:
a support member; and
a mounting member hingably attached with the support member allowing movement of the support member between a first collapsed position and a second operating position, the mounting member comprising an attachment mechanism for removably attaching the support accessory to a surface of the mobile electronic device case.

112. The support accessory of claim 111, wherein when the support accessory is attached to the surface of the mobile electronic device case, and the support member is in the second operating position, the support accessory maintains the mobile electronic device case in at least one semi-upright position when the mobile electronic device case is placed on a surface.

113. The support accessory of claim 111, wherein the support member and the mounting member are a single piece of material.

114. The support accessory of claim 111, wherein the support member and the mounting member are connected with each other by a hinge mechanism.

115. The support accessory of claim 114, wherein the hinge mechanism selected from a group comprising: butt hinges; barrel hinges; flush hinges; piano hinges; springs; bistable springs; buckles; friction mechanisms; sleeves that insert into slots; and channels that interlock with inserts.

116. The support accessory of claim 111 further comprising a handle for facilitating a user in moving the support member between the first collapsed position and the second operating position.

117. The support accessory of claim 116, wherein the handle comprises a recess between the support member and the mounting element.

118. The support accessory of claim 117, wherein the recess is substantially the size of a fingernail.

119. The support accessory of claim 111, wherein the attachment element is at least one magnet and/or magnetic material.

120. The support accessory of claim 111, wherein the surface of the mobile electronic device case is made of a magnetic material.

121. The support accessory of claim 120, wherein the magnetic material is magnetic metal.

122. The support accessory of claim 120, wherein the magnetic material is ferromagnetic material and/or a paramagnetic material.

123. A mobile device connection system, comprising:
a case for a mobile electronic device, the case having a front, a back, a bottom, a top, a first side, and a second side;
wherein at least a portion of the back is made of a magnetic material; and
wherein at least a portion of at least one of the front, bottom, top, first side, and second side is made of one or more non-magnetic materials.

124. The mobile device connection system of claim 123, wherein the back of the case comprises:
a set of first magnetic attachment elements for removably mounting the case to a corresponding set of second magnetic attachment elements attached to an object external to the case; and
a first electrical interface for interfacing with a second electrical interface attached to the object external to the case; and wherein the case comprises:
a third electrical interface attached with the case for connection to a fourth electrical interface on the mobile electronic device, wherein the third electrical interface is electrically connected with the first electrical interface.

125. The mobile device connection system of claim 124, wherein the object external to the case is a charging device comprising:
a housing;
a mounting surface, wherein the second set of magnetic attachment elements and the second electrical interface are adjacent to the mounting surface;
a plug for connection with an electrical outlet, wherein the plug is hingably connected to the charging device and has at least a first charging position and a second storage position relative to the housing, wherein when the plug is in the first charging position, the plug is positioned along an axis substantially perpendicular to a plane formed by the mounting surface.

126. The mobile device connection system of claim 123, wherein substantially all of the back is made of a magnetic material.

127. The mobile device connection system of claim 126, wherein the magnetic material is magnetic metal.

128. The mobile device connection system of claim 126, wherein the magnetic material is a ferromagnetic material and/or a paramagnetic material

129. The mobile device connection system of claim 124, wherein the first and second electrical interfaces are inductive based.

130. The mobile device connection system of claim 124, wherein the first and second electrical interfaces comprise conductive connectors.

131. The mobile device connection system of claim 124, wherein the set of first magnetic attachment elements and the first electrical interface are positioned relative to each other in a first configuration, and the set of second magnetic attachment elements and the second electrical interface are positioned relative to each other in a configuration substantially similar to the first configuration, such that when the first set of magnetic attachment elements is magnetically attached to the second set of magnetic attachment elements, the first and second electrical interfaces are brought into electrical and/or inductive communication.

132. The mobile device connection system of claim 131, wherein the first and second sets of magnetic attachment elements comprise each comprise three magnetic attachment elements positioned to form an isosceles triangle.

133. The mobile device connection system of claim 131, wherein when the first and second electrical interfaces are brought into electrical and/or inductive communication, the fourth electrical interface on the mobile electronic device is in electrical communication with the second electrical interface external to the case.

134. The mobile device connection system of claim 131, wherein the electrical interfaces are configured to transmit electric current such that a battery of the mobile electronic device can be charged.

135. The mobile device connection system of claim 134, wherein the electrical interfaces are further configured to transmit data signals such that the mobile electronic device is in data communication with a second electronic device.

136. The mobile device connection system of claim 135, wherein the second electronic device is a computer, speaker, speaker set, alarm clock, display screen, or image projector.

137. The mobile device connection system of claim 123, wherein the object external to the case is a charging device comprising:
a housing;
a first magnetic attachment element connected with the housing for removably attaching the mobile electronic device case;
a second attachment mechanism for connecting the housing to an object; and
a cable connected with the housing at a first end, the cable comprising a first electrical interface at a second end apart from the first end for connection to a mobile electronic device having a second electrical interface,
wherein the cable and first electrical interface are configured to transmit electric current to the mobile electronic device when the first and second interfaces are brought into electrical communication.

138. The mobile device connection system of claim 137, wherein the charger has a plug connected to the housing of the charger for connecting the charger to a power source.

139. The mobile device connection system of claim 138, wherein the plug is any of a group comprising a USB plug, automobile plug, and/or wall plug.

140. The mobile device connection system of claim 138, wherein the plug is flexibly connected to the mounting device and having a plurality of positions,

141. The mobile device connection system of claim 137, wherein the charger has a plug connected to a wire for connecting the charger to a power source.

142. A mobile electronic device charger, comprising:
a housing with a mounting surface, the mounting surface having a magnetic attachment element for removably connecting a mobile electronic device case; and
a plug for connecting the mobile device charger to a power source, the plug being flexibly connected to the mounting device and having a plurality of positions,
wherein the mounting surface is configured to be movable into a position that allows the mobile electronic device to be viewable by the driver of a vehicle when the plug is connected with the electrical outlet.

143. A mobile device mounting system, comprising:
a case mounting head with a magnetic attachment element for connection to a mobile electronic device case;
a mounting arm; and
a mounting base for connection to a vehicle.

144. The mobile device mounting system of claim 143, wherein the mounting head comprises a first electrical interface for connection to a mobile electronic device case with a second electrical interface, wherein the first and second electrical interface are configured to transmit electric current to the mobile electronic device when the first and second electrical interfaces are brought into electrical communication.

145. The mobile device mounting system of claim 144, further comprising an electrical cable for connection to an electrical system of the vehicle, wherein the electrical cable facilitates the transmission of electrical current between the electrical system of the vehicle and the second electrical interface when the mobile electronic device case is removably attached with the case mounting head.

146. The mobile device mounting system of claim 145, where a mobile electronic device in the mobile electronic device case is in data communication with the electrical system of the vehicle when the mobile electronic device case is removably attached with the case mounting head.

147. The mobile device mounting system of claim 143, further comprising an electrical cable with a first electrical interface for connection to a mobile electronic device having a second electrical interface, wherein the cable and the first electrical interface are configured to transmit electric current to the mobile electronic device when the first and second interfaces are brought into electrical communication.

148. The mobile device mounting system of claim 147, where a mobile electronic device in the mobile electronic device case is in data communication with the electrical system of the vehicle when the first and second interfaces are brought into electrical communication.

149. The mobile device mounting system of claim 143, wherein the case mounting head and the mounting base are connected with the mounting arm by ball-and-socket joints.

150. The mobile device mounting system of claim 143, wherein the mounting arm is a flexible mounting arm.

151. The mobile device mounting system of claim 149, wherein the flexible arm is configured to be bent into and retain a shape.

152. The mobile device mounting system of claim 143, wherein the mounting base comprises an attachment mechanism selected from a group consisting of: suction cups; magnets; magnetic materials; flanges and bolts; adhesives; van der Walls force mechanisms; sleeves that insert into slots; pegs that insert into holes; friction mechanisms; sandbags; and beanbags.

153. A mobile device mounting system, comprising:
a case mounting head with a magnetic attachment element for connection to a mobile electronic device case;
a mounting clip connected with the case mounting head.
